(19) United States
(12) Patent Application Publication
(10) Pub. No.: US 2025/0393439 A1
(43) Pub. Date: Dec. 25, 2025

(54) DISPLAY DEVICE, METHOD FOR MANUFACTURING DISPLAY DEVICE, AND HEAD MOUNTED DISPLAY INCLUDING DISPLAY DEVICE

(71) Applicant: Samsung Display Co., LTD., Yongin-si (KR)

(72) Inventor: Chun Gi YOU, Yongin-si (KR)

(21) Appl. No.: 19/175,973

(22) Filed: Apr. 10, 2025

(30) Foreign Application Priority Data
Jun. 25, 2024 (KR) 10-2024-0082565

(51) Int. Cl. H10K 59/80; H10K 59/122

(52) U.S. Cl. CPC H10K 59/80517; H10K 59/122; H10K 59/80518

(57) ABSTRACT

A display device includes a first sub-pixel including a first emission area for emitting first light, a second sub-pixel including a second emission area for emitting second light, a third sub-pixel including a third emission area for emitting third light, a substrate, an insulating film above the substrate, connection electrodes above the insulating film, reflective electrodes respectively above the connection electrodes, optical auxiliary films respectively above the reflective electrodes, and first electrodes respectively above the optical auxiliary films, wherein a thickness of a first of the optical auxiliary films at the first emission area is less than a thickness of a second of the optical auxiliary films at the second emission area.

### CROSS-REFERENCE TO RELATED APPLICATION

The present application claims priority to, and the benefit of, Korean Patent Application No. 10-2024-0082565, filed on Jun. 25, 2024, in the Korean Intellectual Property Office, the entire disclosure of which is incorporated herein by reference.

### BACKGROUND

### 1. Field

Aspects of one or more embodiments of the present disclosure relate to a display device, a method for manufacturing the display device, and a head-mounted display including the display device.

### 2. Description of the Related Art

A head-mounted display (HMD) is an image display device that is worn on a user's head in the form of glasses or a helmet, and forms a focus at a distance close to user's eyes in front of the user's eyes. The head-mounted display may implement virtual reality (VR) or augmented reality (AR).

The head-mounted display magnifies and displays an image displayed by a small display device using a plurality of lenses. Therefore, a display device applied to the head-mounted display may suitably provide a high-resolution image, for example, an image having a resolution of about 3,000 pixels per inch (PPI) or more. To this end, an organic light-emitting diode on silicon (OLEDoS), which is a small organic light-emitting display device having a high resolution, has been used as the display device applied to the head-mounted display. The OLEDOS is a device that displays an image by arranging organic light-emitting diodes (OLEDs) on a semiconductor wafer substrate including complementary metal oxide semiconductors (CMOSs).

### SUMMARY

Some embodiments of the present disclosure may be directed to a display device capable of providing a high-resolution image.

Some embodiments of the present disclosure may be directed to a method for manufacturing a display device capable of providing a high-resolution image.

Some embodiments of the present disclosure may be directed to a head-mounted display capable of providing a high-resolution image.

However, the present disclosure is not limited to the above aspects. The above and other aspects of the present disclosure will become more apparent to those having ordinary skill in the art by referencing the description below.

According to one or more embodiments of the present disclosure, a display device includes a first sub-pixel including a first emission area for emitting first light, a second sub-pixel including a second emission area for emitting second light, a third sub-pixel including a third emission area for emitting third light, a substrate, an insulating film above the substrate, connection electrodes above the insulating film, reflective electrodes respectively above the connection electrodes, optical auxiliary films respectively above the reflective electrodes, and first electrodes respectively above the optical auxiliary films, wherein a thickness of a first of the optical auxiliary films at the first emission area is less than a thickness of a second of the optical auxiliary films at the second emission area.

The thickness of the first of the optical auxiliary films may be less than a thickness of a third of the optical auxiliary films at the third emission area.

The thickness of the second of the optical auxiliary films may be the same as a thickness of a third of the optical auxiliary films at the third emission area.

The thickness of the second of the optical auxiliary films may be less than a thickness of a third of the optical auxiliary films at the third emission area.

A height of a first of the first electrodes at the first emission area may be less than a height of a second of the first electrodes at the second emission area.

The height of the first of the first electrodes may be less than a height of a third of the first electrodes at the third emission area.

The height of the second of the first electrodes may be the same as a height of a third of the first electrodes at the third emission area.

The height of the second of the first electrodes may be less than a height of a third of the first electrodes at the third emission area.

The first electrodes may be respectively on side surfaces of the connection electrodes, side surfaces of the reflective electrodes, and an upper surface and side surfaces of the optical auxiliary films.

The display device may further include a first pixel-defining film covering a portion of upper surfaces of the first electrodes above the optical auxiliary films, and covering the first electrodes on the side surfaces of the connection electrodes, the side surfaces of the reflective electrodes, and the side surfaces of the optical auxiliary films, and a planarization film above the first pixel-defining film.

The planarization film may be above an upper surface of a first of the first electrodes at the first emission area.

An upper surface of the first pixel-defining film at the second emission area and at the third emission area and an upper surface of the planarization film may be flatly connected to each other.

The planarization film may be above the upper surfaces of a first one of the first electrodes at the first emission area and a second one of the first electrodes at the second emission area.

A thickness of the planarization film above the upper surface of the first of the first electrodes may be less than a thickness of the planarization film above an upper surface of the second of the first electrodes.

An upper surface of the first pixel-defining film above an upper surface of a third of the first electrodes at the third emission area and an upper surface of the planarization film may be flatly connected to each other.

A thickness of the planarization film above the upper surface of the first of the first electrodes and the upper surface of the second of the first electrodes may be less than a thickness of the planarization film above the upper surface of the third of the first electrodes.

The display device may further include a second pixel-defining film above the first pixel-defining film and the planarization film, and a third pixel-defining film above the second pixel-defining film, wherein a length of the second pixel-defining film in one direction is less than a length of the third pixel-defining film in the one direction.

The display device may further include a first power conductive layer above the insulating film, and including a same material as the connection electrode, a second power conductive layer above the first power conductive layer, and including a same material as the reflective electrode, a third power conductive layer above the second power conductive layer, and a fourth power conductive layer connected to the third power conductive layer through a contact hole penetrating through the optical auxiliary film above the third power conductive layer, wherein the first pixel-defining film exposes a portion of an upper surface of the fourth power conductive layer.

The display device may further include a light-emitting layer above the first electrodes, and a second electrode above the light-emitting layer, and connected to the portion of the upper surface of the fourth power conductive layer.

According to one or more embodiments of the present disclosure, a method for manufacturing a display device includes forming a connection electrode layer above a substrate, forming a reflective electrode layer on the connection electrode layer, forming an optical auxiliary layer above the reflective electrode layer, etching a portion of the optical auxiliary layer using a first mask, forming connection electrodes, reflective electrodes, and optical auxiliary films by etching the connection electrode layer, the reflective electrode layer, and the optical auxiliary layer using a second mask, forming a first electrode layer covering the connection electrodes, the reflective electrodes, and the optical auxiliary films, forming first electrodes respectively on side surfaces of the connection electrodes, side surfaces of the reflective electrodes, and an upper surface and side surfaces of the optical auxiliary films by etching the first electrode layer using a third mask, forming a first pixel-defining layer covering the first electrodes, forming a planarization film above the first pixel-defining layer to planarize a step due to the connection electrodes, the reflective electrodes, and the optical auxiliary films, forming a second pixel-defining layer above the first pixel-defining layer and the planarization film, forming a third pixel-defining layer above the second pixel-defining layer, forming a third pixel-defining film by etching the third pixel-defining layer, forming a first pixel-defining film and a second pixel-defining film exposing the first electrodes by forming a mask pattern covering the third pixel-defining film, etching the first pixel-defining layer and the second pixel-defining layer, forming a light-emitting stack above the first electrodes, forming a second electrode above the light-emitting stack, and forming an encapsulation layer covering the second electrode.

According to one or more embodiments of the present disclosure, a head-mounted display includes at least one display device including a first sub-pixel including a first emission area for emitting first light, a second sub-pixel including a second emission area for emitting second light, and a third sub-pixel including a third emission area for emitting third light, a display device housing in which the at least one display device is housed, and an optical member magnifying a display image of the at least one display device or converting an optical path, wherein the at least one display device includes a substrate, an insulating film above the substrate, connection electrodes above the insulating film, reflective electrodes respectively above the connection electrodes, optical auxiliary films respectively above the reflective electrodes, and first electrodes respectively above the optical auxiliary films, and a thickness of a first of the optical auxiliary films at the first emission area is less than a thickness of a second of the optical auxiliary films at the second emission area among the optical auxiliary films.

According to one or more embodiments of the present disclosure, an electronic device includes a display device including a first sub-pixel including a first emission area for emitting first light, a second sub-pixel including a second emission area for emitting second light, a third sub-pixel including a third emission area for emitting third light, a substrate, an insulating film above the substrate, connection electrodes above the insulating film, reflective electrodes respectively above the connection electrodes, optical auxiliary films respectively above the reflective electrodes, and first electrodes respectively above the optical auxiliary films, wherein a thickness of a first of the optical auxiliary films at the first emission area is less than a thickness of a second of the optical auxiliary films at the second emission area.

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

According to some embodiments of the present disclosure, in a method for manufacturing the display device, and in a head-mounted display device including the display device, a plurality of optical auxiliary films are formed through a photolithography process using a mask without a chemical mechanical polishing (CMP) process, thus making control of thicknesses of the plurality of optical auxiliary films suitable. Therefore, a thickness deviation between the plurality of optical auxiliary films may be reduced, and it is possible to reduce or prevent a difference in light emission efficiency from occurring due to a difference in resonance distance caused by the thickness deviation between the plurality of optical auxiliary films for each area of a display panel. Accordingly, color blurring occurring on the display panel may be reduced or minimized.

However, the present disclosure is not limited to the above aspects, and the above and additional aspects will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects of the present disclosure will be more clearly understood from the following detailed description of the illustrative, non-limiting embodiments with reference to the accompanying drawings, in which:

FIG. 1 is an exploded perspective view illustrating a display device according to one or more embodiments;

FIG. 2 is a block diagram illustrating the display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIG. 5 is a layout diagram illustrating an example of a display area of FIG. 4;

FIG. 6 is a layout diagram illustrating another example of the display area of FIG. 4;

FIG. 7 is a cross-sectional view illustrating an example of the display panel taken along the line I1-I1′ of FIG. 5;

FIG. 8 is a cross-sectional view illustrating an example of area A1 of FIG. 7 in detail;

FIG. 9 is an illustrative view illustrating a connection electrode, a reflective electrode, a first electrode, a light-emitting stack, and a second electrode in each of a first sub-pixel, a second sub-pixel, and a third sub-pixel of FIG. 8;

FIG. 10 is a cross-sectional view illustrating an example of area B1 of FIG. 8 in detail;

FIG. 11 is a cross-sectional view illustrating an example of area B2 of FIG. 8 in detail;

FIG. 12 is a cross-sectional view illustrating an example of the display panel taken along the line I2-I2′ of FIG. 4;

FIG. 13 is a cross-sectional view illustrating an example of area C1 of FIG. 12 in detail;

FIG. 14 is a cross-sectional view illustrating another example of the display panel taken along the line I1-I1′ of FIG. 5;

FIG. 15 is a cross-sectional view illustrating an example of area A2 of FIG. 14 in detail;

FIG. 16 is a flowchart illustrating a method for manufacturing a display panel according to one or more embodiments;

FIGS. 17 to 28 are cross-sectional views illustrating area A1 in detail to describe the method for manufacturing a display panel according to one or more embodiments;

FIG. 29 is a perspective view illustrating a head-mounted display device according to one or more embodiments;

FIG. 30 is an exploded perspective view illustrating an example of the head-mounted display device of FIG. 29; and

FIG. 31 is a perspective view illustrating a head-mounted display according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Software components may indicate data used by executable codes and/or executable codes in a storage medium which is able to be addressed. Accordingly, software components may be, for example, object-oriented software components, class components, and task components, and may include processes, functions, properties, procedures, subroutines, program code segments, drivers, firmware, microcodes, circuits, data, database, data structures, tables, arrangements or variables. Further, the various components of these devices may be a process or thread, running on one or more processors, in one or more computing devices, executing computer program instructions and interacting with other system components for performing the various functionalities described herein. The computer program instructions are stored in a memory that may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the embodiments of the present disclosure.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

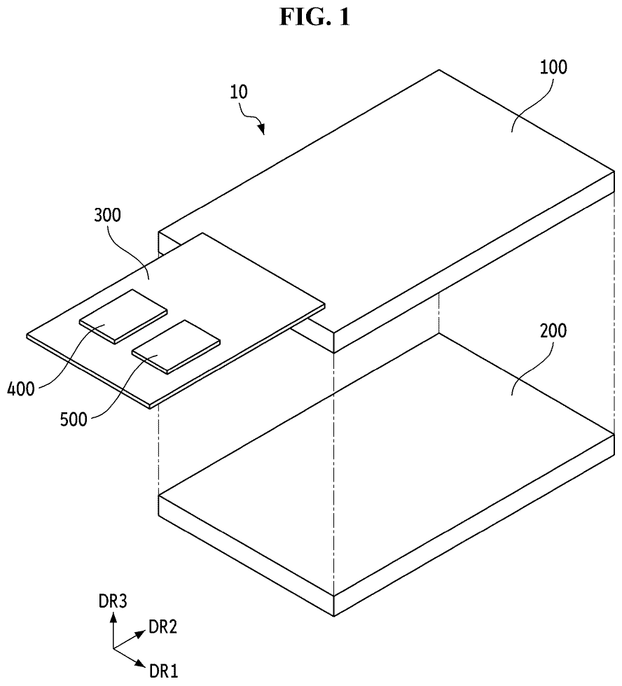

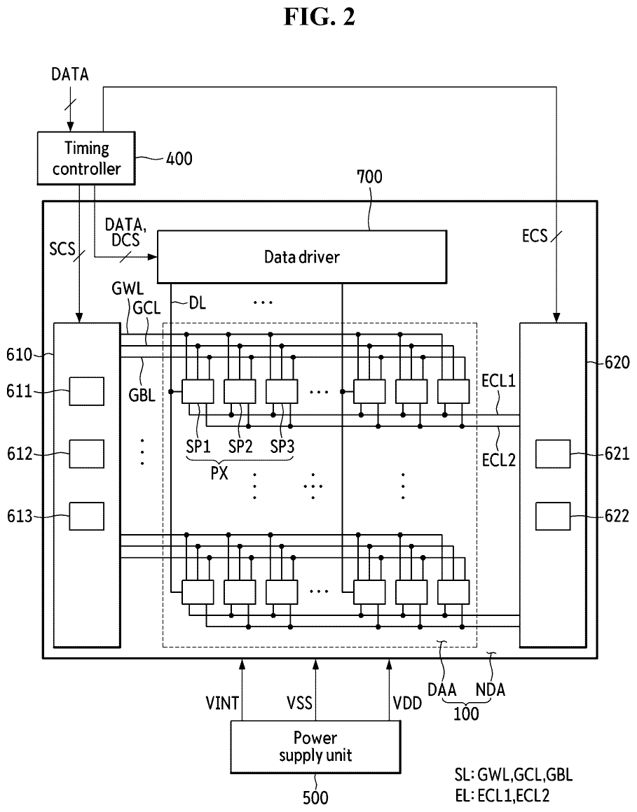

FIG. 1 is an exploded perspective view illustrating a display device according to one or more embodiments. FIG. 2 is a block diagram illustrating the display device according to one or more embodiments.

Referring to FIGS. 1 and 2, a display device 10 according to one or more embodiments is a device that displays a moving image or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according one or more embodiments may be applied as a display unit of televisions, laptop computers, monitors, billboards, or the Internet of Things (IoTs). Alternatively, the display device 10 according one or more embodiments may be applied to smart watches, watch phones, or head-mounted displays (HMDs) for implementing virtual reality and augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in plan view. For example, the display panel 100 may have a shape similar to a rectangular shape, in plan view, having short sides in a first direction DR1, and long sides in a second direction DR2 crossing the first direction DR1. In the display panel 100, a corner where the short side in the first direction DR1 and the long side in the second direction DR2 meet may be rounded with a corresponding curvature or right-angled. A shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but one or more embodiments of the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA that displays an image and a non-display area NDA that does not display an image, as illustrated in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, and may be located in the second direction DR2. The plurality of data lines DL may extend in the second direction DR2, and may be located in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

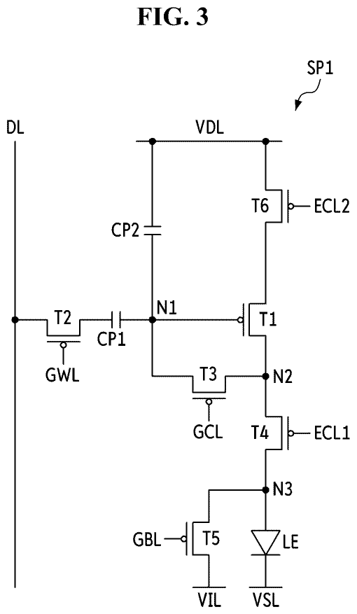

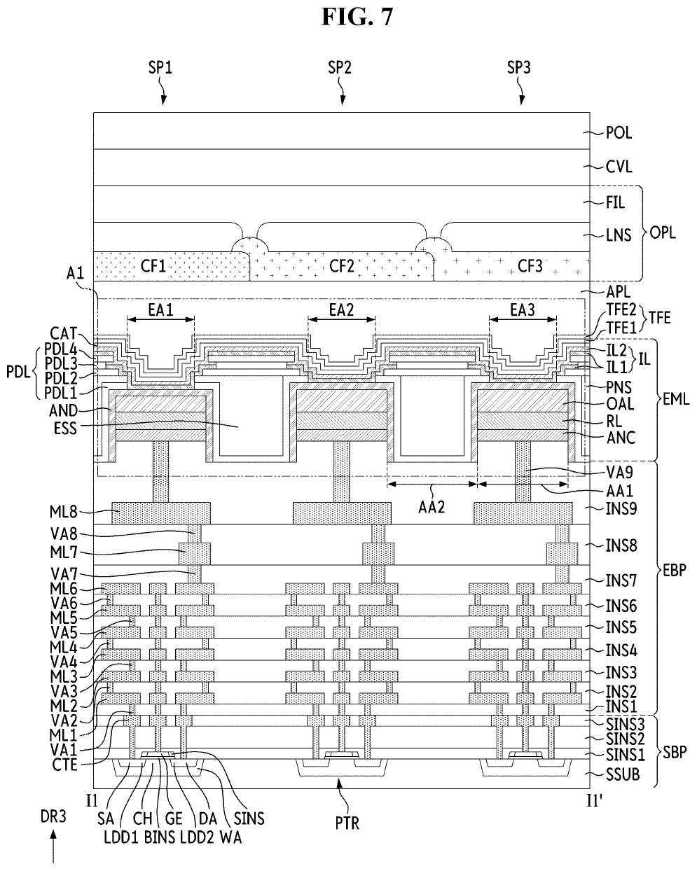

Each of the plurality of pixels PX includes a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed by a semiconductor process, and may be located on a semiconductor substrate SSUB (see FIG. 7). For example, a plurality of pixel transistors of the data driver 700 may be formed as complementary metal oxide semiconductors (CMOSs), but one or more embodiments of the present disclosure is not limited thereto.

Each of the plurality of sub-pixels SP1, SP2, and SP3 may be connected to any one of the plurality of write scan lines GWL, any one of the plurality of control scan lines GCL, any one of the plurality of bias scan lines GBL, any one of the plurality of first emission control lines ECL1, any one of the plurality of second emission control lines ECL2, and/or any one of the plurality of data lines DL. Each of the plurality of sub-pixels SP1, SP2, and SP3 may receive a data voltage of the data line DL according to a write scan signal of the write scan line GWL, and may allow a light-emitting element to emit light according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors. The plurality of scan transistors and the plurality of light-emitting transistors may be formed by a semiconductor process and formed on a semiconductor substrate SSUB (see FIG. 7). For example, the plurality of scan transistors and the plurality of light-emitting transistors may be formed as CMOSs, but one or more embodiments of the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing controller 400. The write scan signal output unit 611 may generate write scan signals according to the scan-timing control signal SCS of the timing controller 400, and may sequentially output the write scan signals to the write scan lines GWL. The control scan signal output unit 612 may generate control scan signals according to the scan-timing control signal SCS, and may sequentially output the control scan signals to the control scan lines GCL. The bias scan signal output unit 613 may generate bias scan signals according to the scan-timing control signal SCS, and may sequentially output the bias scan signals to the bias scan lines GBL.

The emission driver 620 includes a first emission control driver 621 and a second emission control driver 622. Each of the first emission control driver 621 and the second emission control driver 622 may receive an emission-timing control signal ECS from the timing controller 400. The first emission control driver 621 may generate first emission control signals according to the emission-timing control signal ECS, and may sequentially output the first emission control signals to the first emission control lines ECL1. The second emission control driver 622 may generate second emission control signals according to the emission-timing control signal ECS, and may sequentially output the second emission control signals to the second emission control lines ECL2.

The data driver 700 may include a plurality of data transistors, and the plurality of data transistors may be formed by a semiconductor process and formed on a semiconductor substrate SSUB (see FIG. 7). For example, the plurality of data transistors may be formed as CMOSs, but one or more embodiments of the present disclosure is not limited thereto.

The data driver 700 may receive digital video data DATA and a data-timing control signal DCS from the timing controller 400. The data driver 700 converts the digital video data DATA into analog data voltages according to the data-timing control signal DCS, and outputs the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, for example, a rear surface, of the display panel 100. The heat dissipation layer 200 serves to dissipate heat generated from the display panel 100. The heat dissipation layer 200 may include a layer including graphite or metal such as silver (Ag), copper (Cu), or aluminum (Al) having high thermal conductivity.

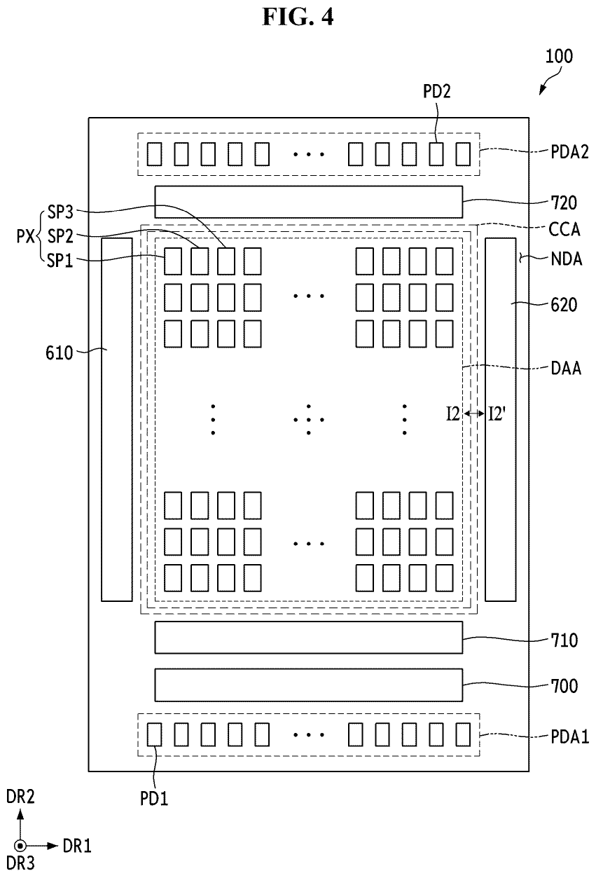

The circuit board 300 may be electrically connected to a plurality of first pads PD1 (see FIG. 4) of a first pad unit PDA1 (see FIG. 4) of the display panel 100 using a conductive adhesive member such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be located on the rear surface of the display panel 100 and/or a rear surface of the heat dissipation layer 200. The other end of the circuit board 300 may be connected to the plurality of first pads PD1 (see FIG. 4) of the first pad unit PDA1 (see FIG. 4) of the display panel 100 using the conductive adhesive member. One end of the circuit board 300 may be an end opposite to the other end of the circuit board 300.

The timing controller 400 may receive digital video data and timing signals from the outside. The timing controller 400 may generate the scan-timing control signal SCS, the emission-timing control signal ECS, and the data-timing control signal DCS for controlling the display panel 100 according to the timing signals. The timing controller 400 may output the scan-timing control signal SCS to the scan driver 610, and may output the emission-timing control signal ECS to the emission driver 620. The timing controller 400 may output the digital video data and the data-timing control signal DCS to the data driver 700.

The power supply unit 500 may generate a plurality of panel driving voltages according to an external source voltage. For example, the power supply unit 500 may generate a first driving voltage VSS, a second driving voltage VDD, and a third driving voltage VINT, and may supply the first driving voltage VSS, the second driving voltage VDD, and the third driving voltage VINT to the display panel 100. The first driving voltage VSS, the second driving voltage VDD, and the third driving voltage VINT will be described later with reference to FIG. 3.

Each of the timing controller 400 and the power supply unit 500 may be formed as an integrated circuit (IC), and may be attached to one surface of the circuit board 300. In this case, the scan-timing control signal SCS, the emission-timing control signal ECS, the digital video data DATA, and the data-timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

Alternatively, each of the timing controller 400 and the power supply unit 500 may be located in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and formed on a semiconductor substrate SSUB (see FIG. 7). For example, the plurality of timing transistors and the plurality of power transistors may be formed as CMOSs, but one or more embodiments of the present disclosure is not limited thereto. Each of the timing controller 400 and the power supply unit 500 may be located between the data driver 700 and the first pad unit PDA1 (see FIG. 4).

FIG. 3 is an equivalent circuit diagram of a first sub-pixel according to one or more embodiments.

Referring to FIG. 3, a first sub-pixel SP1 may be connected to a write scan line GWL, a control scan line GCL, a bias scan line GBL, a first emission control line ECL1, a second emission control line ECL2, and a data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage that is lower than the third driving voltage VINT. The second driving voltage VDD may be a voltage that is higher than the third driving voltage VINT.

The first sub-pixel SP1 includes a plurality of transistors T1 to T6, a light-emitting element LE, a first capacitor CP1, and a second capacitor CP2.

The light-emitting element LE emits light according to a source-drain current (hereinafter referred to as a “driving current”) flowing through a channel of a first transistor T1. An amount of light emitted from the light-emitting element LE may be proportional to the driving current. The light-emitting element LE may be located between a fourth transistor T4 and the first driving voltage line VSL. A first electrode of the light-emitting element LE may be connected to a drain electrode of the fourth transistor T4, and a second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but one or more embodiments of the present disclosure is not limited thereto. For example, the light-emitting element LE may be an inorganic light-emitting element including a first electrode, a second electrode, and an inorganic semiconductor located between the first electrode and the second electrode, and in this case, the light-emitting element LE may be a micro light-emitting diode.

The first transistor T1 may be a driving transistor for controlling the driving current flowing between a source electrode and a drain electrode according to a voltage applied to a gate electrode thereof. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL to connect one electrode of the first capacitor CP1 to the data line DL. For this reason, a data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be located between the first node N1 and the second node N2. The third transistor T3 is turned on by a control scan signal of the control scan line GCL to connect the first node N1 to the second node N2. For this reason, the gate electrode and the source electrode of the first transistor T1 are connected to each other, and thus, the first transistor T1 may operate as a diode. The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line ECL1 to connect the second node N2 to the third node N3. For this reason, the driving current of the first transistor T1 may be supplied to the light-emitting element LE. The fourth transistor T4 includes a gate electrode connected to the first emission control line ECL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line GBL to connect the third node N3 to the third driving voltage line VIL. For this reason, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line ECL2 to connect the source electrode of the first transistor T1 to the second driving voltage line VDL. For this reason, the second driving voltage VDD of the second driving voltage line VDL may be applied to the source electrode of the first transistor T1. The sixth transistor T6 includes a gate electrode connected to the second emission control line ECL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light-emitting element LE.

Each of the first to sixth transistors T1 to T6 may be a metal oxide semiconductor field effect transistor (MOSFET). For example, each of the first to sixth transistors T1 to T6 may be a P-type MOSFET, but one or more embodiments of the present disclosure is not limited thereto. Each of the first to sixth transistors T1 to T6 may be an N-type MOSFET. Alternatively, one or more of the first to sixth transistors T1 to T6 may be P-type MOSFETs, and one or more others of the first to sixth transistors T1 to T6 may be N-type MOSFETs.

It has been illustrated in FIG. 3 that the first sub-pixel SP1 includes six transistors T1 to T6 and two capacitors C1 and C2, but it is to be noted that an equivalent circuit diagram of the first sub-pixel SP1 is not limited to that illustrated in FIG. 3. For example, the numbers of transistors and capacitors of the first sub-pixel SP1 are not limited to those illustrated in FIG. 3.

In addition, an equivalent circuit diagram of a second sub-pixel SP2 and an equivalent circuit diagram of a third sub-pixel SP3 may be substantially the same as the equivalent circuit diagram of the first sub-pixel SP1 described with reference to FIG. 3. Therefore, a description of the equivalent circuit diagram of the second sub-pixel SP2 and the equivalent circuit diagram of the third sub-pixel SP3 is omitted in the present disclosure.

FIG. 4 is a layout diagram illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, one or more embodiments of the present disclosure is not limited thereto, and the scan drivers 610 and the emission drivers 620 may be located on both the first and second sides of the display area DAA.

The first pad unit PDA1 may include a plurality of first pads PD1 connected to pads or bumps of the circuit board 300 through a conductive adhesive member. The first pad unit PDA1 may be located on a third side of the display area DAA. For example, the first pad unit PDA1 may be located on one side of the display area DAA in the second direction DR2. The first pad unit PDA1 may be located outside the data driver 700 in the second direction DR2. That is, the first pad unit PDA1 may be located closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The second pad unit PDA2 may be located on a fourth side of the display area DAA. For example, the second pad unit PDA2 may be located on the other side of the display area DAA in the second direction DR2. The second pad unit PDA2 may be located outside the second distribution circuit 720 in the second direction DR2. That is, the second pad unit PDA2 may be located closer to an edge of the display panel 100 than the second distribution circuit 720 is.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be located on the fourth side of the display area DAA of the display panel 100. For example, the second distribution circuit 720 may be located on the other side of the display area DAA in the second direction DR2. That is, the second distribution circuit 720 may be located on the upper side of the display area DAA.

A cathode connection portion CCA may be an area where a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, the cathode connection portion CCA may be located outside at least one of the left side, the right side, the upper side, and the lower side of the display area DAA. Alternatively, the cathode connection portion CCA may be located to surround the display area DAA (e.g., in plan view), as in FIG. 4, to reduce or minimize a deviation of the first driving voltage VSS due to a voltage drop (IR drop) or voltage rising (IR rising) of the second electrode CAT in the display area DAA.

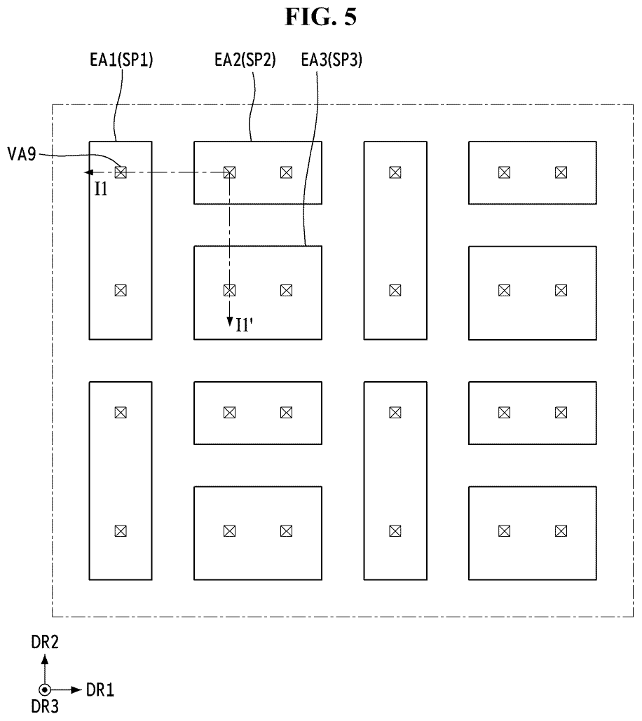

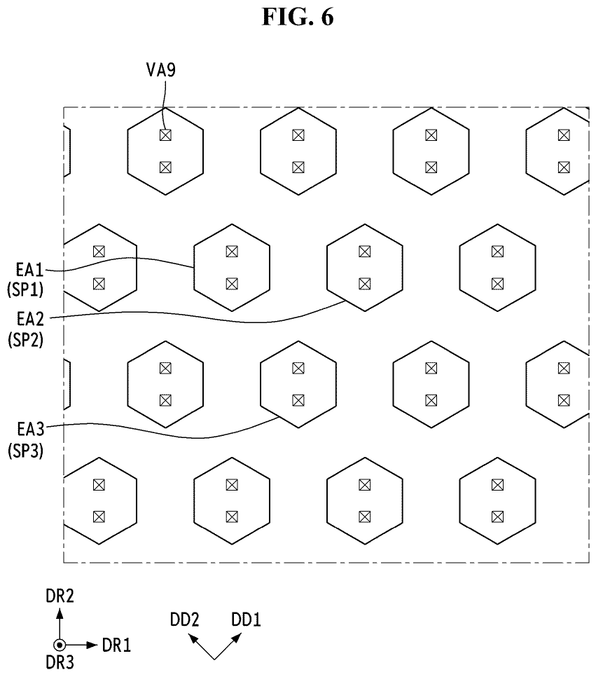

FIGS. 5 and 6 are layout diagrams illustrating embodiments of a display area of FIG. 4.

Referring to FIGS. 5 and 6, each of the plurality of pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have a polygonal shape, a circular shape, an elliptical shape, or an irregular shape in plan view.

A maximum length of the first emission area EA1 in the first direction DR1 may be less than a maximum length of the second emission area EA2 in the first direction DR1, and less than a maximum length of the third emission area EA3 in the first direction DR1. The maximum length of the second emission area EA2 in the first direction DR1 and the maximum length of the third emission area EA3 in the first direction DR1 may be substantially the same as each other.

A maximum length of the first emission area EA1 in the second direction DR2 may be greater than a maximum length of the second emission area EA2 in the second direction DR2, and and greater than a maximum length of the third emission area EA3 in the second direction DR2. The maximum length of the second emission area EA2 in the second direction DR2 may be less than the maximum length of the third emission area EA3 in the second direction DR2.

Each of the first emission area EA1, the second emission area EA2, and the third emission area EA3 may have a hexagonal shape including six straight lines, in plan view, as illustrated in FIG. 6, but one or more embodiments of the present disclosure is not limited thereto. Each of the first emission area EA1, the second emission area EA2, and the third emission area EA3 may have polygonal shapes other than the hexagonal shape, a circular shape, an elliptical shape, or an irregular shape in plan view.

As illustrated in FIG. 5, in each of the plurality of pixels PX, the first emission area EA1 and the second emission area EA2 may neighbor to each other in the first direction DR1. In addition, the first emission area EA1 and the third emission area EA3 may neighbor to each other in the first direction DR1. In addition, the second emission area EA2 and the third emission area EA3 may neighbor to each other in the second direction DR2. An area of the first emission area EA1, an area of the second emission area EA2, and an area of the third emission area EA3 may be different from each other.

Alternatively, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2, and may refer to a direction inclined by 45° with respect to the first direction DR1 and the second direction DR2, and the second diagonal direction DD2 may be a direction substantially orthogonal to the first diagonal direction DD1.

The first sub-pixel SP1 may emit first light that has passed through a first color filter CF1 (see FIG. 7) among light emitted from the first emission area EA1, the second sub-pixel SP2 may emit second light that has passed through a second color filter CF2 (see FIG. 7) among light emitted from the second emission area EA2, and the third sub-pixel SP3 may emit third light that has passed through a third color filter CF3 (see FIG. 7) among light emitted from the third emission area EA3. Here, the first light may be light of a red wavelength band, the second light may be light of a green wavelength band, and the third light may be light of a blue wavelength band. For example, the blue wavelength band may indicate that a main peak wavelength of the light is included in a wavelength band of approximately 370 nm to approximately 460 nm, the green wavelength band may indicate that a main peak wavelength of the light is included in a wavelength band of approximately 480 nm to approximately 560 nm, and the red wavelength band may indicate that a main peak wavelength of the light is included in a wavelength band of approximately 600 nm and approximately 750 nm.

It has been illustrated in FIGS. 5 and 6 that each of the plurality of pixels PX includes three emission areas EA1, EA2, and EA3, but one or more embodiments of the present disclosure is not limited thereto. That is, each of the plurality of pixels PX may also include four emission areas.

In addition, an arrangement of the emission areas of the plurality of pixels PX is not limited to those illustrated in FIGS. 5 and 6. For example, the emission areas of the plurality of pixels PX may be located in a stripe structure in which the emission areas are arranged in the first direction DR1, a PenTile® structure (PenTile® being a registered trademark of Samsung Display Co., Ltd., Republic of Korea), in which the emission areas have a diamond arrangement, or a hexagonal structure in which emission areas having a hexagonal shape in plan view are arranged as illustrated in FIG. 6.

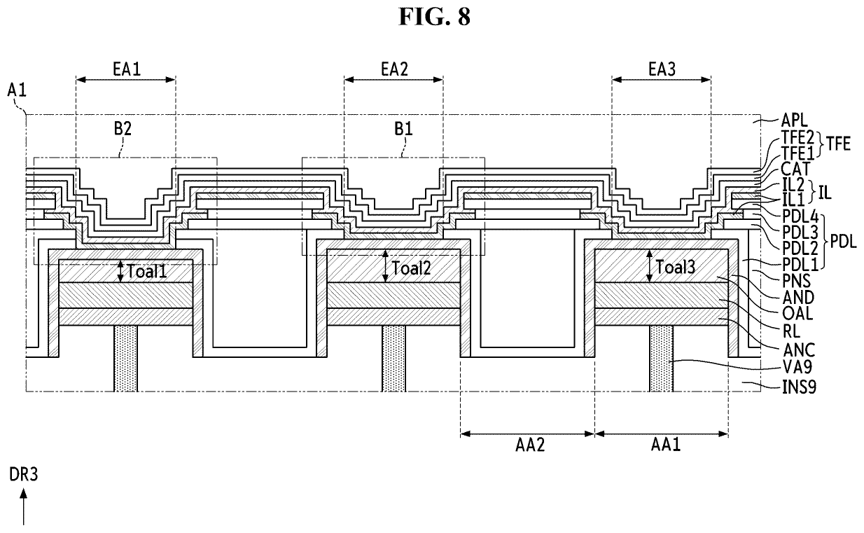

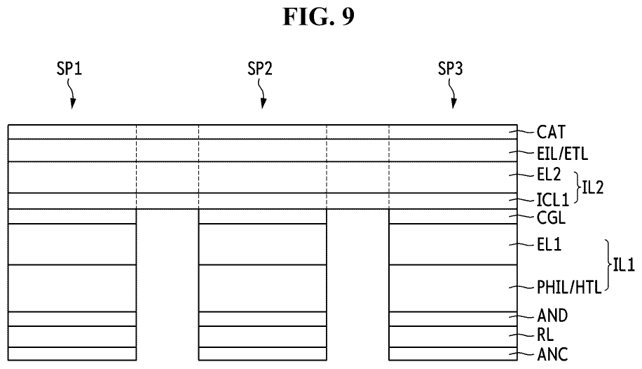

FIG. 7 is a cross-sectional view illustrating an example of the display panel taken along the line I1-I1′ of FIG. 5. FIG. 8 is a cross-sectional view illustrating area A1 of FIG. 7 in detail. FIG. 9 is an illustrative view illustrating a connection electrode, a reflective electrode, a first electrode, a light-emitting stack, and a second electrode in each of a first sub-pixel, a second sub-pixel, and a third sub-pixel of FIG. 8.

Referring to FIGS. 7 and 8, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be located in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH located between the source region SA and the drain region DA.

A bottom insulating film BINS may be located between a gate electrode GE and the well region WA. Side surface insulating films SINS may be located on side surfaces of the gate electrode GE. The side surface insulating films SINS may be located on the bottom insulating film BINS.

Each of the source region SA and the drain region DA may be a region doped with the first-type impurities. The gate electrode GE of the pixel transistor PTR may overlap the well region WA in the third direction DR3, which is a thickness direction of the semiconductor substrate SSUB. The channel region CH may overlap the gate electrode GE in the third direction DR3. The source region SA may be located on one side of the gate electrode GE, and the drain region SA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be reduced or prevented.

A first semiconductor insulating film SINS1 may be located on the semiconductor substrate SSUB. The first semiconductor insulating film SINS1 may be formed as a silicon carbonitride (SiCN) or silicon oxide (SiOₓ)-based inorganic film, but one or more embodiments of the present disclosure is not limited thereto.

A second semiconductor insulating film SINS2 may be located on the first semiconductor insulating film SINS1. The second semiconductor insulating film SINS2 may be formed as a silicon oxide (SiOₓ)-based inorganic film, but one or more embodiments of the present disclosure is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through a hole penetrating through the first semiconductor insulating film SINS1 and the second semiconductor insulating film INS2. Each of the plurality of contact terminals CTE may be made of any one of copper (Cu), aluminum (Al), tungsten (W), molybdenum (Mo), chromium (Cr), gold (Au), titanium (Ti), nickel (Ni), or neodymium (Nd), or alloys thereof.

A third semiconductor insulating film SINS3 may be located on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but one or more embodiments of the present disclosure is not limited thereto.

The semiconductor substrate SSUB may be replaced with a glass substrate or a polymer resin substrate such as a polyimide substrate. In this case, thin film transistors may be located on the glass substrate or the polymer resin substrate. The glass substrate may be a rigid substrate that is not bent, and the polymer resin substrate may be a flexible substrate that may be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 located between first to eighth conductive layers ML1 to ML8.

The first to eighth conductive layers ML1 to ML8 serve to implement a circuit of the first sub-pixel SP1 illustrated in FIG. 3 by connecting the plurality of contact terminals CTE exposed from the semiconductor backplane SBP to each other. For example, only the first to sixth transistors T1 to T6 are formed in the semiconductor backplane SBP, and the connection between the first to sixth transistors T1 to T6 and the formation of the first capacitor CP1 and the second capacitor CP2 are performed through the first to eighth conductive layers ML1 to ML8. In addition, the connection between a drain region corresponding to a drain electrode of the fourth transistor T4, a source region corresponding to a source electrode of the fifth transistor T5, and a first electrode AND of the light-emitting element LE is also performed through the first to eighth conductive layers ML1 to ML8.

A first insulating film INS1 may be located on the semiconductor backplane SBP. Each of first vias VA1 may penetrate through the first film INS1 to be connected to the contact terminal CTE exposed from the semiconductor backplane SBP. Each of the first conductive layers ML1 may be located on the first insulating film INS1, and may be connected to the first via VA1.

A second insulating film INS2 may be located on the first insulating film INS1 and the first conductive layers ML1. Each of second vias VA2 may penetrate through the second insulating film INS2 to be connected to the exposed first conductive layer ML1. Each of the second conductive layers ML2 may be located on the second insulating film INS2, and may be connected to the second via VA2.

A third insulating film INS3 may be located on the second insulating film INS2 and the second conductive layers ML2. Each of third vias VA3 may penetrate through the third insulating film INS3 to be connected to the exposed second conductive layer ML2. Each of the third conductive layers ML3 may be located on the third insulating film INS3, and may be connected to the third via VA3.

A fourth insulating film INS4 may be located on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be located on the fourth insulating film INS4, and may be connected to the fourth via VA4.

A fifth insulating film INS4 may be located on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be located on the fifth insulating film INS5, and may be connected to the fifth via VA5.

A sixth insulating film INS6 may be located on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be located on the sixth insulating film INS6, and may be connected to the sixth via VA6.

A seventh insulating film INS7 may be located on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be located on the seventh insulating film INS7, and may be connected to the seventh via VA7.

An eighth insulating film INS8 may be located on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be located on the eighth insulating film INS8, and may be connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), or neodymium (Nd), or alloys thereof. The first to eighth vias VA1 to VA8 may be made of substantially the same material. The first to eighth insulating films INS1 to INS8 may be formed as silicon oxide (SiOₓ)-based inorganic films, but one or more embodiments of the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1,000 Å to approximately 1,500 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1,000 Å to approximately 1,500 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 4,000 Å to approximately 9,000 Å. Each of the thickness of the seventh via VA7 and the thickness of the eighth via VA8 may be approximately 6,000 Å to approximately 7,000 Å.

A ninth insulating film INS9 may be located on the eighth insulating film INS8 and the eighth conductive layer ML8. The ninth insulating film INS9 may be formed as a silicon oxide (SiOₓ)-based inorganic film, but one or more embodiments of the present disclosure is not limited thereto.

Each of ninth vias VA9 may penetrate through the ninth insulating film INS9 to be connected to the exposed eighth conductive layer ML8. Each of the ninth vias VA9 may be made of any one of copper (Cu), aluminum (Al), tungsten (W), molybdenum (Mo), chromium (Cr), gold (Au), titanium (Ti), nickel (Ni), or neodymium (Nd), or alloys thereof. A thickness of the ninth via VA9 may be approximately 6,000 Å to approximately 7,000 Å.

The display element layer EML may be located on the light-emitting element backplane EBP. The display element layer EML may include a plurality of connection electrodes ANC, a plurality of reflective electrodes RL, a planarization film PNS, a pixel-defining film PDL, a plurality of first electrodes AND, a light-emitting stack IL, and a second electrode CAT.

In addition, the display element layer EML may include a first emission area EA1, a second emission area EA2, and a third emission area EA3. Each of the first emission area EA1, the second emission area EA2, and the third emission area EA3 may be an area where the first electrode AND, the light-emitting stack IL, and the second electrode CAT are sequentially stacked. Each of the first emission area EA1, the second emission area EA2, and the third emission area EA3 may be an area where a light-emitting element LE including the first electrode AND, the light-emitting stack IL, and the second electrode CAT are located. Each of the first emission area EA1, the second emission area EA2, and the third emission area EA3 may be partitioned by the pixel-defining film PDL.

The ninth insulating film INS9 may include first portions AA1 overlapping the plurality of connection electrodes ANC, and a second portion AA2 located around the first portions AA1.

The plurality of connection electrodes ANC may be located on the first portions AA1 of the ninth insulating film INS9, respectively. Each of the plurality of connection electrodes ANC may be located on the first portion AA1 of the ninth insulating film INS9 corresponding thereto. Each of the plurality of connection electrodes ANC may be made of any one of copper (Cu), aluminum (Al), tungsten (W), molybdenum (Mo), chromium (Cr), gold (Au), titanium (Ti), nickel (Ni), or neodymium (Nd), alloys thereof, or transparent conductive oxide. For example, each of the plurality of connection electrodes ANC may include titanium (Ti), titanium nitride (TiN), indium tin oxide (ITO), or indium zinc oxide (IZO), but one or more embodiments of the present disclosure is not limited thereto. A thickness of each of the plurality of connection electrodes ANC may be approximately 600 Å.

The plurality of reflective electrodes RL may be located on the plurality of connection electrodes ANC, respectively. Each of the plurality of reflective electrodes RL may be located on the connection electrode ANC corresponding thereto. Each of the plurality of reflective electrodes RL may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the plurality of reflective electrodes RL may include aluminum (Al) having high reflectivity.

A plurality of optical auxiliary films OAL may be located on the plurality of reflective electrodes RL, respectively. Each of the plurality of optical auxiliary films OAL may be located on the reflective electrode RL corresponding thereto. Each of the plurality of optical auxiliary films OAL may be formed as a silicon oxide (SiOₓ)-based inorganic film, but one or more embodiments of the present disclosure is not limited thereto.

As shown in FIG. 8, a thickness Toal1 of the optical auxiliary film OAL in the first emission area EA1 may be less than a thickness Toal2 of the optical auxiliary film OAL in the second emission area EA2, and less than a thickness Toal3 of the optical auxiliary film OAL in the third emission area EA3. The thickness Toal1 of the optical auxiliary film OAL in the first emission area EA1, the thickness Toal2 of the optical auxiliary film OAL in the second emission area EA2, and the thickness Toal3 of the optical auxiliary film OAL in the third emission area EA3 may be set in consideration of a wavelength of light emitted from a first light-emitting layer EL1 (see FIG. 9) of the light-emitting stack IL, a resonance distance of the light emitted from the first light-emitting layer EL1 (see FIG. 9), a wavelength of light emitted from a second light-emitting layer EL2 (see FIG. 9) of the light-emitting stack IL, and a resonance distance of the light emitted from the second light-emitting layer EL2 (see FIG. 9).

Each of the light-emitting elements LE may include the first electrode AND, the light-emitting stack IL, and the second electrode CAT.

The first electrode AND of each of the light-emitting elements LE may be located on the optical auxiliary film OAL corresponding thereto. Because the connection electrode ANC, the reflective electrode RL, and the optical auxiliary film OAL are sequentially stacked, the first electrode AND of each of the light-emitting elements LE may be located on an upper surface and side surfaces of the optical auxiliary film OAL, side surfaces of the reflective electrode RL, and side surfaces of the connection electrode ANC. For this reason, the first electrode AND of each of the light-emitting elements LE may be in contact with, and electrically connected to, the side surfaces of the reflective electrode RL and the side surfaces of the connection electrode ANC. Therefore, there may be an aspect that the number of mask processes may be reduced compared to a case where the first electrode AND of each of the light-emitting elements LE is connected to the reflective electrode RL exposed through a through hole penetrating through the optical auxiliary film OAL, and thus, a manufacturing cost may be reduced, and manufacturing efficiency may be increased.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

In addition, a thickness of the first portion AA1 of the ninth insulating film INS9 may be greater than a thickness of the second portion AA2 of the ninth insulating film INS9. For this reason, the first portion AA1 of the ninth insulating film INS9 may be exposed, and the first electrode AND of each of the light-emitting elements LE may be located on side surfaces of the exposed first portion AA1 of the ninth insulating film INS9. Therefore, a length of the first electrode AND in the third direction DR3 may be greater than the sum of a length of the side surface of the connection electrode ANC, a length of the side surface of the reflective electrode RL, and a length of the side surface of the optical auxiliary film OAL.

The first electrode AND of each of the light-emitting elements LE may be made of any one of copper (Cu), aluminum (Al), tungsten (W), molybdenum (Mo), chromium (Cr), gold (Au), titanium (Ti), nickel (Ni), or neodymium (Nd), alloys thereof, or transparent conductive oxide. For example, the first electrode AND of each of the light-emitting elements LE may include titanium nitride (TiN), ITO, or IZO, but one or more embodiments of the present disclosure is not limited thereto.

The thickness Toal1 of the optical auxiliary film OAL in the first emission area EA1 may be less than the thickness Toal2 of the optical auxiliary film OAL in the second emission area EA2, and less than the thickness Toal3 of the optical auxiliary film OAL in the third emission area EA3. For this reason, a height of the first portion AA1 of the ninth insulating film INS9, the connection electrode ANC, the reflective electrode RL, and the optical auxiliary film OAL in the first emission area EA1 may be less than a height of the first portion AA1 of the ninth insulating film INS9, the connection electrode ANC, the reflective electrode RL, and the optical auxiliary film OAL in the second emission area EA2 and in the third emission area EA3. For this reason, a height of the first electrode AND located in (e.g., at) the first emission area EA1 may be less than, or lower than, a height of the first electrode AND located in each of the second emission area EA2 and in the third emission area EA3. The height of the first electrode AND located in the first emission area EA1 may be defined as a maximum length of the first electrode AND located in the first emission area EA1, in the third direction DR3.

The pixel-defining film PDL may be located on a portion of the first electrode AND of each of the light-emitting elements LE. The pixel-defining film PDL may cover an edge of the first electrode AND of each of the light-emitting elements LE. The pixel-defining film PDL may partition the first emission areas EA1, the second emission areas EA2, and the third emission areas EA3.

The first emission area EA1 may be defined as an area where the first electrode AND, the light-emitting stack IL, and the second electrode CAT are sequentially stacked in the first sub-pixel SP1 to emit light. The second emission area EA2 may be defined as an area where the first electrode AND, the light-emitting stack IL, and the second electrode CAT are sequentially stacked in the second sub-pixel SP2 to emit light. The third emission area EA3 may be defined as an area where the first electrode AND, the light-emitting stack IL, and the second electrode CAT are sequentially stacked in the third sub-pixel SP3 to emit light.

The pixel-defining film PDL may include first to fourth pixel-defining films PDL1, PDL2, PDL3, and PDL4.

The first pixel-defining film PDL1 may be located on the first electrode AND of each of the light-emitting elements LE. For example, the first pixel-defining film PDL1 may cover a portion of an upper surface of the first electrode AND located on the optical auxiliary film OAL. In addition, the first pixel-defining film PDL1 may cover the first electrode AND located on the side surfaces of the first portion AA1 of the ninth insulating film INS9, the side surfaces of the connection electrode ANC, the side surfaces of the reflective electrode RL, and the side surfaces of the optical auxiliary film OAL. The first pixel-defining film PDL1 may be located on an upper surface of the second portion AA2 of the ninth insulating film INS9.

The planarization film PNS is a film for planarizing a step due to the first portion AA1 of the ninth insulating film INS9, the connection electrode ANC, the reflective electrode RL, and the optical auxiliary film OAL.

The planarization film PNS may be located on the first pixel-defining film PDL1 covering the first electrode AND, which is located on the side surfaces of the first portion AA1 of the ninth insulating film INS9, the side surfaces of the connection electrode ANC, the side surfaces of the reflective electrode RL, and the side surfaces of the optical auxiliary film OAL. The planarization film PNS may be located on the first pixel-defining film PDL1 at the second portion AA2 of the ninth insulating film INS9.

The planarization film PNS may be located between the connection electrodes ANC neighboring to each other in the first direction DR1 or the second direction DR2. The planarization film PNS may be located between the reflective electrodes RL neighboring to each other in the first direction DR1 or the second direction DR2. The planarization film PNS may be located between the optical auxiliary films OAL neighboring to each other in the first direction DR1 or the second direction DR2.

The thickness Toal1 of the optical auxiliary film OAL in the first emission area EA1 may be less than the thickness Toal2 of the optical auxiliary film OAL in the second emission area EA2, and less the thickness Toal3 of the optical auxiliary film OAL in the third emission area EA3. For this reason, the height of the first portion AA1 of the ninth insulating film INS9, the connection electrode ANC, the reflective electrode RL, and the optical auxiliary film OAL in the first emission area EA1 may be less than the height of the first portion AA1 of the ninth insulating film INS9, the connection electrode ANC, the reflective electrode RL, and the optical auxiliary film OAL in the second emission area EA2 and in the third emission area EA3. Therefore, the planarization film PNS may cover an upper surface of the first pixel-defining film PDL1, which is located on an upper surface of the first electrode AND, at the first emission area EA1.

In contrast, an upper surface of the planarization film PNS and an upper surface of the first electrode AND located in each of the second emission area EA2 and the third emission area EA3 may be flatly connected to each other. In other words, the planarization film PNS may not cover an upper surface of the first pixel-defining film PDL1, which is located on the upper surface of the first electrode AND, at each of the second emission area EA2 and the third emission area EA3.

The second pixel-defining film PDL2 may be located on the first pixel-defining film PDL1 and the planarization film PNS, the third pixel-defining film PDL3 may be located on the second pixel-defining film PDL2, and the fourth pixel-defining film PDL4 may be located on the third pixel-defining film PDL3. The first pixel-defining film PDL1 and the third pixel-defining film PDL3 may be formed as silicon nitride (SiNₓ)-based inorganic films, whereas the second pixel-defining film PDL2, the fourth pixel-defining film PDL4, and the planarization film PNS may be formed silicon oxide (SiOₓ)-based inorganic films. The first pixel-defining film PDL1 is made of a different material from the planarization film PNS, and may thus serve as a stopper in a process of performing chemical mechanical polishing on the planarization film PNS.

Each of a thickness of the first pixel-defining film PDL1, a thickness of the second pixel-defining film PDL2, and a thickness of the third pixel-defining film PDL3 may be approximately 500 Å, but one or more embodiments of the present disclosure is not limited thereto.

A length of the first pixel-defining film PDL1 in one direction may be greater than a length of the second pixel-defining film PDL2 in one direction. The length of the second pixel-defining film PDL2 in one direction may be greater than a length of the third pixel-defining film PDL3 in one direction, and greater than a length of the fourth pixel-defining film PDL4 in one direction. The length of the third pixel-defining film PDL3 in one direction may be less than the length of the fourth pixel-defining film PDL4 in one direction. Here, one direction may refer to one direction on a plane defined by the first direction DR1 and the second direction DR2.

Because the length of the third pixel-defining film PDL3 in one direction is less than the length of the fourth pixel-defining film PDL4 in one direction, a lower surface of the fourth pixel-defining film PDL4 may be exposed without being covered by the third pixel-defining film PDL3. That is, the third pixel-defining film PDL3 and the fourth pixel-defining film PDL4 may have a cross-sectional structure with an eaves shape, or a mushroom shape.

The light-emitting stack IL may be located on the first electrode AND and the pixel-defining film PDL. The light-emitting stack IL may include a first stack layer IL1 and a second stack layer IL2 that emit different light, as illustrated in FIG. 9. When the light-emitting stack IL has a two-tandem structure, any one of the first stack layer IL1 or the second stack layer IL2 may emit light including a wavelength range of any one of the first light, the second light, or the third light, and the other of the first stack layer IL1 and the second stack layer IL2 may emit light including wavelength ranges of the other two of the first light, the second light, or the third light. For example, the first stack layer IL1 may emit light including a wavelength range of the first light, and the second stack layer IL2 may emit light including a wavelength range of the second light and a wavelength range of the third light.

The first stack layer IL1 may have a structure in which a hole-transporting layer HTL or a hole injection layer PHIL, and a first light-emitting layer EL1, which is for emitting the light including the wavelength range of the first light, are sequentially stacked. The first light-emitting layer EL1 may be an organic light-emitting layer.

The second stack layer IL2 may have a structure in which a first interconnection layer ICL1 and a second light-emitting layer EL2, which is for emitting the light including the wavelength range of the second light and the wavelength range of the third light, are sequentially stacked. The first interconnection layer ICL1 may include at least one of a hole-transporting layer and a hole injection layer. The second light-emitting layer EL2 may be an organic light-emitting layer.

A charge generation layer CGL for supplying charges to the second stack layer IL2 and for supplying electrons to the first stack layer IL1 may be located between the first stack layer IL1 and the second stack layer IL2. The charge generation layer GCL may include an n-type charge generation layer for supplying electrons to the first stack layer IL1, and a p-type charge generation layer for supplying holes to the second stack layer IL2. The n-type charge generation layer may include a dopant of a metal material.

An electron injection layer EIL or an electron-transporting layer ETL may be located on the second stack layer IL2 and the second electrode CAT.

The first stack layer IL1 may not be formed on, or may be omitted from, the lower surface of the fourth pixel-defining film PDL4 exposed without being covered by, or overlapped by, the third pixel-defining film PDL3, and may thus be disconnected by the cross-sectional structure due to the eaves shape/mushroom shape of the third pixel-defining film PDL3 and the fourth pixel-defining film PDL4. In this case, the charge generation layer CGL located between the first stack layer IL1 and the second stack layer IL2 may also be disconnected. Therefore, it is possible to reduce or prevent a current from flowing between the emission areas EA1, EA2, and EA3 neighboring to each other through the charge generation layer CGL. Accordingly, it is possible to reduce or prevent the likelihood of the light-emitting stack IL in the emission areas EA1, EA2, and EA3 neighboring to each other being affected by the current, and emitting light other than originally intended light.

It has been illustrated in FIG. 9 that the light-emitting stack IL has the two-tandem structure including two stack layers IL1 and IL2, but one or more embodiments of the present disclosure is not limited thereto. For example, the light-emitting stack IL may have a three-tandem structure including three stack layers. In this case, the light-emitting stack IL may include first to third stack layers, and a thickness of the optical auxiliary film OAL in the first emission area EA1 may be set in consideration of a wavelength of light emitted from a first light-emitting layer of the first stack layer and a resonance distance of the light emitted from the first light-emitting layer. In addition, a thickness of the optical auxiliary film OAL in the second emission area EA2 may be set in consideration of a wavelength of light emitted from a second light-emitting layer of the second stack layer and a resonance distance of the light emitted from the second light-emitting layer. In addition, a thickness of the optical auxiliary film OAL in the third emission area EA3 may be set in consideration of a wavelength of light emitted from a third light-emitting layer of the third stack layer and a resonance distance of the light emitted from the third light-emitting layer. Accordingly, the thickness of the optical auxiliary film OAL in the first emission area EA1, the thickness of the optical auxiliary film OAL in the second emission area EA2, and the thickness of the optical auxiliary film OAL in the third emission area EA3 may be different from each other. For example, the thickness of the optical auxiliary film OAL in the first emission area EA1 may be less than the thickness of the optical auxiliary film OAL in the second emission area EA2, and the thickness of the optical auxiliary film OAL in the second emission area EA2 may be less than the thickness of the optical auxiliary film OAL in the third emission area EA3.

The second electrode CAT may be located on the light-emitting stack IL. The second electrode CAT may be made of a semi-transmissive conductive material such as magnesium (Mg), silver (Ag), or an alloy of magnesium (Mg) and/or silver (Ag). In this case, the light emitted from the light-emitting stack IL may be subjected to a micro cavity between the reflective electrode RL and the second electrode CAT, and light emission efficiency in each of the first to third sub-pixels SP1, SP2, and SP3 may be increased.

The encapsulation layer TFE may be located on the display element layer EML. The encapsulation layer TFE may include at least one inorganic film TFE1 or TFE2 to reduce or prevent oxygen or moisture from permeating into the display element layer EML. For example, the encapsulation layer TFE may include a first encapsulation inorganic film TFE1 and a second encapsulation inorganic film TFE2.

The first encapsulation inorganic film TFE1 may be located on the second electrode CAT. The first encapsulation inorganic film TFE1 may be formed as multiple films in which one or more inorganic films of a silicon nitride (SiNₓ) film, a silicon oxynitride (SiON) film, and/or a silicon oxide (SiOₓ) film are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed as a titanium oxide (TiOₓ) film or an aluminum oxide (AlOₓ) film, but one or more embodiments of the present disclosure is not limited thereto. The second encapsulation inorganic film TFE2 may be formed by an atomic layer deposition (ALD) process. A thickness of the second encapsulation inorganic film TFE2 may be less than a thickness of the first encapsulation inorganic film TFE1.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the organic film APL.

The first color filter CF1 may overlap the first emission area EA1 of the first sub-pixel SP1. The first color filter CF1 may transmit the first light, that is, the light of the red wavelength band, therethrough. Therefore, the first color filter CF1 may transmit the first light among light emitted from the light-emitting stack IL of the first emission area EA1 therethrough.

The second color filter CF2 may overlap the second emission area EA2 of the second sub-pixel SP2. The second color filter CF2 may transmit the second light, that is, the light of the green wavelength band, therethrough. Therefore, the second color filter CF2 may transmit the second light among light emitted from the light-emitting stack IL of the second emission area EA2 therethrough.

The third color filter CF3 may overlap the third emission area EA3 of the third sub-pixel SP3. The third color filter CF3 may transmit the third color, that is, the light of the blue wavelength band, therethrough. Therefore, the third color filter CF3 may transmit the third light among light emitted from the light-emitting stack IL of the third emission area EA3 therethrough.

The lenses LNS may be respectively located on each of the first color filter CF1, the second color filter CF2, and the third color filter CF3. Each of the plurality of lenses LNS may be a structure for increasing a ratio of light directed to a front surface of the display device 10. It has been illustrated that each of the plurality of lenses LNS has a cross-sectional shape that is convex in an upward direction, but one or more embodiments of the present disclosure is not limited thereto.

The filling layer FIL may be located on the plurality of lenses LNS. The filling layer FIL may have a refractive index (e.g., predetermined refractive index) so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be located on the filling layer FIL. The cover layer CVL may be a glass substrate or a polymer resin, such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin, such as the resin, the cover layer CVL may be directly applied onto the filling layer FIL.

The polarizing plate POL may be located on one surface of the cover layer CVL. The polarizing plate POL may be a structure for reducing or preventing deterioration in visibility due to external light reflection. The polarizing plate POL may include a linear polarizing plate and a phase retardation film. For example, the phase retardation film may be a N/4 plate (quarter-wave plate), but one or more embodiments of the present disclosure is not limited thereto. However, when the deterioration in visibility due to the external light reflection is sufficiently improved by the first to third color filters CF1, CF2, and CF3, the polarizing plate POL may be omitted.

As illustrated in FIGS. 7 and 8, the display element layer EML including the light-emitting elements LE is located on the semiconductor substrate SSUB formed by the semiconductor process, which is a micro process or an ultra-micro process, and thus, a high-resolution image of about 3,000 pixels per inch (PPI) or more may be provided.

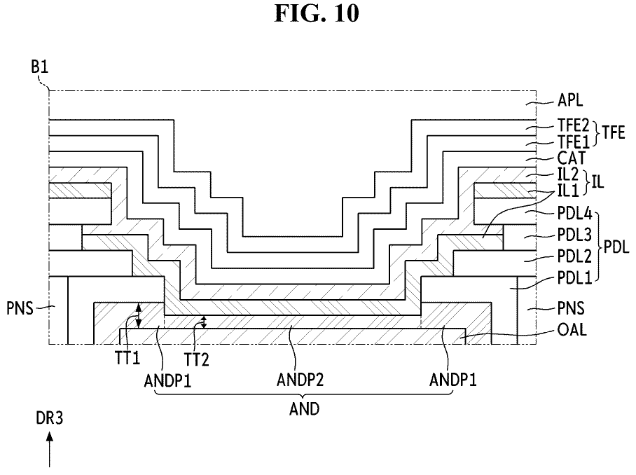

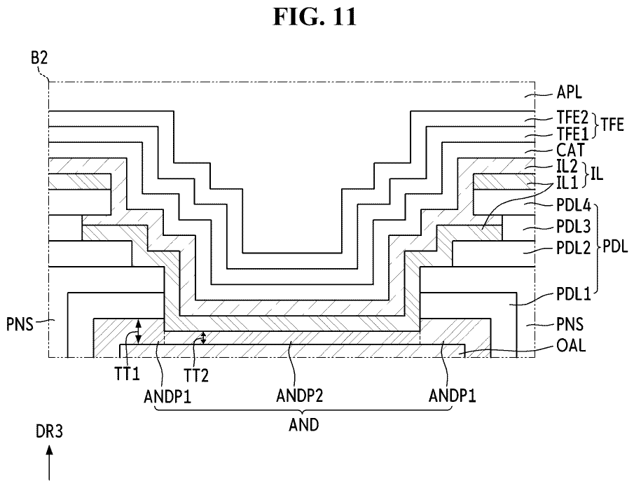

FIG. 10 is a cross-sectional view illustrating an example of area B1 of FIG. 8 in detail. FIG. 11 is a cross-sectional view illustrating an example of area B2 of FIG. 8 in detail.

Referring to FIGS. 10 and 11, the first electrode AND includes a first portion ANDP1 and a second portion ANDP2. The first portion ANDP1 of the first electrode AND may be a portion of the first electrode AND that overlaps the pixel-defining film PDL in the third direction DR3. The first portion ANDP1 of the first electrode AND may be covered by the pixel-defining film PDL.

The second portion ANDP2 of the first electrode AND may be a portion of the first electrode AND that does not overlap the pixel-defining film PDL in the third direction DR3. The second portion ANDP2 of the first electrode AND may be exposed without being covered by the pixel-defining film PDL.

A thickness TT2 of the second portion ANDP2 of the first electrode AND may be less than a thickness TT1 of the first portion ANDP1 of the first electrode AND. For example, the thickness TT2 of the second portion ANDP2 of the first electrode AND may be approximately 50 Å to approximately 80 Å. The thickness TT1 of the first portion ANDP1 of the first electrode AND may be approximately 500 Å or less.

Because the thickness TT2 of the second portion ANDP2 of the first electrode AND is less than the thickness TT1 of the first portion ANDP1 of the first electrode AND, light transmissivity of the second portion ANDP2 of the first electrode AND may be higher than light transmissivity of the first portion ANDP1 of the first electrode AND. For this reason, a ratio of light resonating between the reflective electrode RL and the second electrode CAT among light emitted from the first light-emitting layer EL1 of the first stack layer IL1 may increase. Similarly, a ratio of light resonating between the reflective electrode RL and the second electrode CAT among light emitted from the second light-emitting layer EL2 of the second stack layer IL2 may also increase. Therefore, a ratio of emitted light may be increased by the micro cavity of the light between the reflective electrode RL and the second electrode CAT. Accordingly, luminous efficiency of the first emission area EA1, luminous efficiency of the second emission area EA2, and luminous efficiency of the third emission area EA3 may be improved.

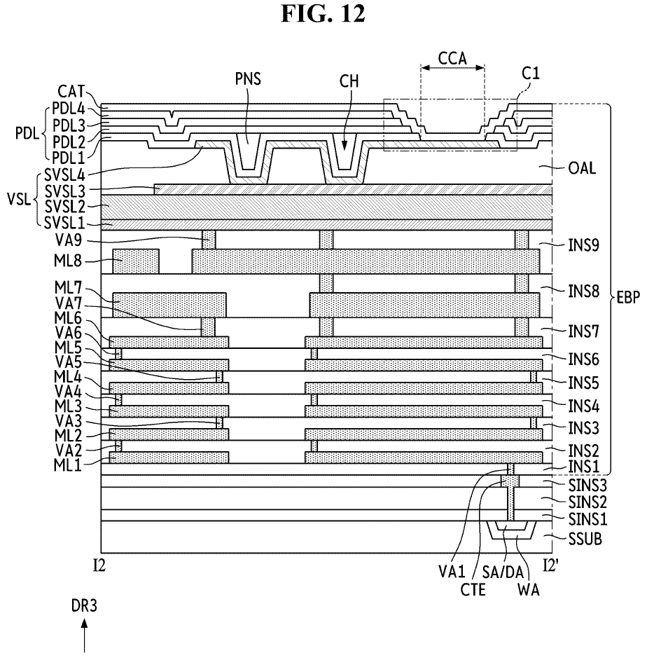

FIG. 12 is a cross-sectional view illustrating an example of the display panel taken along the line I2-I2′ of FIG. 4. A cross-sectional structure of the cathode connection portion CCA of FIG. 4 is illustrated in FIG. 12.

Referring to FIG. 12, the cathode connection portion CCA may be an area where the second electrode CAT is electrically connected to the first driving voltage line VSL in the non-display area NDA.

The first driving voltage line VSL may include a first power conductive layer SVSL1, a second power conductive layer SVSL2, a third power conductive layer SVSL3, and a fourth power conductive layer SVSL4 that are sequentially stacked.

The first power conductive layer SVSL1 may include the same material as the plurality of connection electrodes ANC. The first power conductive layer SVSL1 may be made of any one of copper (Cu), aluminum (Al), tungsten (W), molybdenum (Mo), chromium (Cr), gold (Au), titanium (Ti), nickel (Ni), or neodymium (Nd), alloys thereof, or transparent conductive oxide. For example, the first power conductive layer SVSL1 may include titanium (Ti), titanium nitride (TiN), ITO, or IZO, but one or more embodiments of the present disclosure is not limited thereto.

The second power conductive layer SVSL2 may include the same material as the plurality of reflective electrodes RL. The second power conductive layer SVSL2 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, the second power conductive layer SVSL2 may include aluminum (Al) having high reflectivity.

The third power conductive layer SVSL3 may be a protective layer for protecting the second power conductive layer SVSL2 from an etching material when forming a contact hole CH penetrating through the optical auxiliary film OAL. The third power conductive layer SVSL3 may include titanium (Ti), titanium nitride (TiN), ITO, or IZO, but one or more embodiments of the present disclosure is not limited thereto.

The optical auxiliary film OAL may be located on the third power conductive layer SVSL3.

The fourth power conductive layer SVSL4 may be located on the optical auxiliary film OAL, and may be connected to the third power conductive layer SVSL3 through the contact hole CH penetrating the optical auxiliary film OAL. The fourth power conductive layer SVSL4 may include the same material as the plurality of first electrodes AND. The fourth power conductive layer SVSL4 may be made of any one of copper (Cu), aluminum (Al), tungsten (W), molybdenum (Mo), chromium (Cr), gold (Au), titanium (Ti), nickel (Ni), or neodymium (Nd), alloys thereof, or transparent conductive oxide. For example, the fourth power conductive layer SVSL4 may include titanium nitride (TiN), ITO, or IZO, but one or more embodiments of the present disclosure is not limited thereto.

A thickness of the first power conductive layer SVSL1 may be substantially the same as the thickness of each of the plurality of connection electrodes ANC. A thickness of the second power conductive layer SVSL2 may be substantially the same as a thickness of each of the plurality of reflective electrodes RL.

The pixel-defining film PDL may be located on a portion of the fourth power conductive layer SVSL4. The planarization film PNS may be located between the first pixel-defining film PDL1 and the second pixel-defining film PDL2 in the contact hole CH.

The second electrode CAT may be connected to the fourth power conductive layer SVSL4 exposed without being covered by the pixel-defining film PDL. The second electrode CAT may be connected to the first driving voltage line VSL in the non-display area NDA to stably receive the first driving voltage VSS.

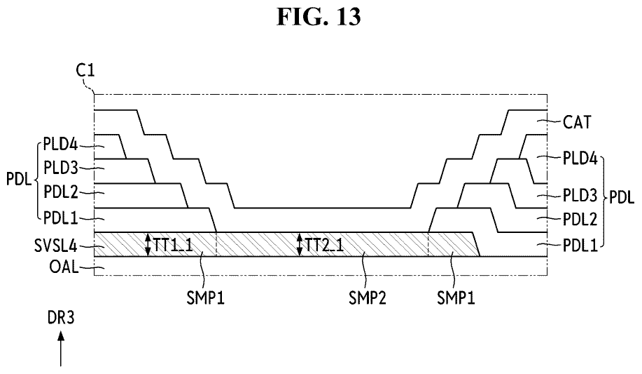

FIG. 13 is a cross-sectional view illustrating an example of area C1 of FIG. 12 in detail.

Referring to FIG. 13, the fourth power conductive layer SVSL4 includes a first portion SMP1 and a second portion SMP2.

The first portion SMP1 of the fourth power conductive layer SVSL4 may be a portion of the fourth power conductive layer SVSL4 that overlaps the pixel-defining film PDL in the third direction DR3. The first portion SMP1 of the fourth power conductive layer SVSL4 may be covered by the pixel-defining film PDL.

The second portion SMP2 of the fourth power conductive layer SVSL4 may be a portion of the fourth power conductive layer SVSL4 that does not overlap the pixel-defining film PDL in the third direction DR3. The second portion SMP2 of the fourth power conductive layer SVSL4 may be exposed without being covered by the pixel-defining film PDL.

In the emission areas EA1, EA2, and EA3, the thickness TT2 of the second portion ANDP2 of the first electrode AND is less than the thickness TT1 of the first portion ANDP1 of the first electrode AND to increase the light transmissivity of the first electrode AND, but in the cathode connection portion CCA, there is no need to reduce a thickness of the fourth power conductive layer SVSL4 when considering contact resistance. Therefore, a thickness TT1_1 of the first portion SMP1 of the fourth power conductive layer SVSL4 and a thickness TT2_1 of the second portion SMP2 of the fourth power conductive layer SVSL4 may be substantially the same as each other.

In addition, the thickness TT1_1 of the first portion SMP1 and the thickness TT2_1 of the second portion SMP2 of the fourth power conductive layer SVSL4 may be substantially the same as the thickness TT1 of the first portion ANDP1 of each of the plurality of first electrodes AND. In addition, the thickness TT1_1 of the first portion SMP1 and the thickness TT2_1 of the second portion SMP2 of the fourth power conductive layer SVSL4 may be greater than the thickness TT2 of the second portion ANDP2 of each of the plurality of first electrodes AND.

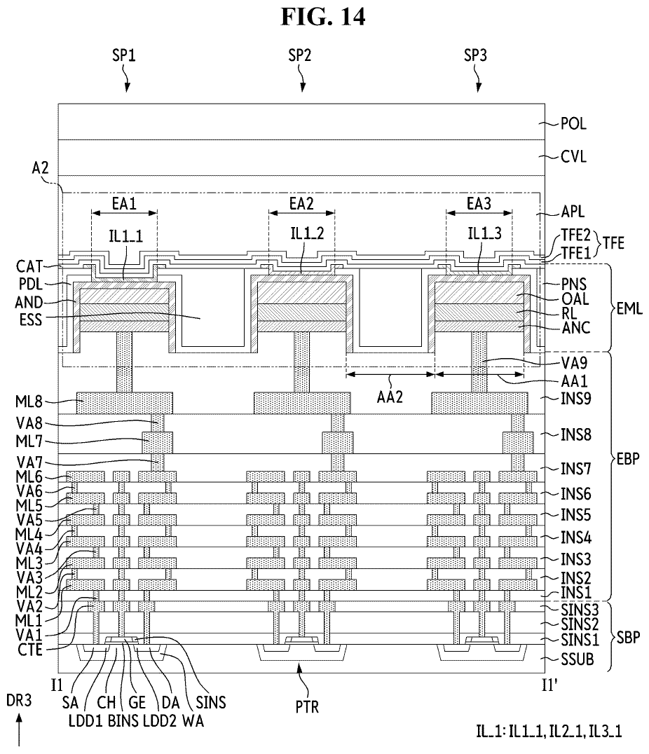

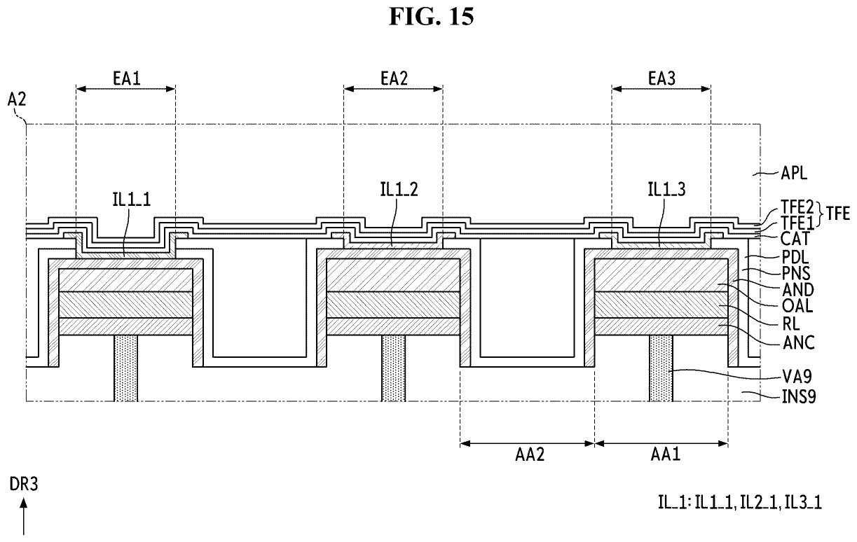

FIG. 14 is a cross-sectional view illustrating another example of the display panel taken along the line I1-I1′ of FIG. 5. FIG. 15 is a cross-sectional view illustrating an example of area A2 of FIG. 14 in detail.

Embodiments of FIGS. 14 and 15 are different from embodiments corresponding FIGS. 7 and 8 in that the second to fourth pixel-defining films PDL2, PDL3, and PDL4, the first to third color filters CF1, CF2, and CF3, the lenses LNS, and the filling layer FIL are omitted and the light-emitting stack IL is replaced with a first light-emitting layer IL1_1, a second light-emitting layer IL2_1, and a third light-emitting layer IL3_1. In FIGS. 14 and 15, contents different from those of one or more embodiments of FIGS. 7 and 8 will be mainly described.

Referring to FIGS. 14 and 15, the first light-emitting layer IL1_1 may be located on the first electrode AND exposed without being covered by the first pixel-defining film PDL1 in the first emission area EA1. The first light-emitting layer IL1_1 may also be located on a portion of the first pixel-defining film PDL1.

The second light-emitting layer IL2_1 may be located on the first electrode AND exposed without being covered by the first pixel-defining film PDL1 in the second emission area EA2. The second light-emitting layer IL2_1 may also be located on a portion of the first pixel-defining film PDL1.

The third light-emitting layer IL3_1 may be located on the first electrode AND exposed without being covered by the first pixel-defining film PDL1 in the third emission area EA3. The first light-emitting layer IL1_1 may also be located on a portion of the pixel-defining film PDL.

The first light-emitting layer IL1_1, the second light-emitting layer IL2_1, and the third light-emitting layer IL3_1 may be spaced apart from each other. Therefore, the second to fourth pixel-defining films PDL2, PDL3, and PDL4 for disconnecting the light-emitting stack IL may be omitted.

Because the first light-emitting layer IL1_1 of the first emission area EA1 emits the first light, because the second light-emitting layer IL2_1 of the second emission area EA2 emits the second light, and because the third light-emitting layer IL3_1 of the third emission area EA3 emits the third light, the first to third color filters CF1, CF2, and CF3, the plurality of lenses LNS, and the filling layer FIL of the optical layer OPL may be omitted.

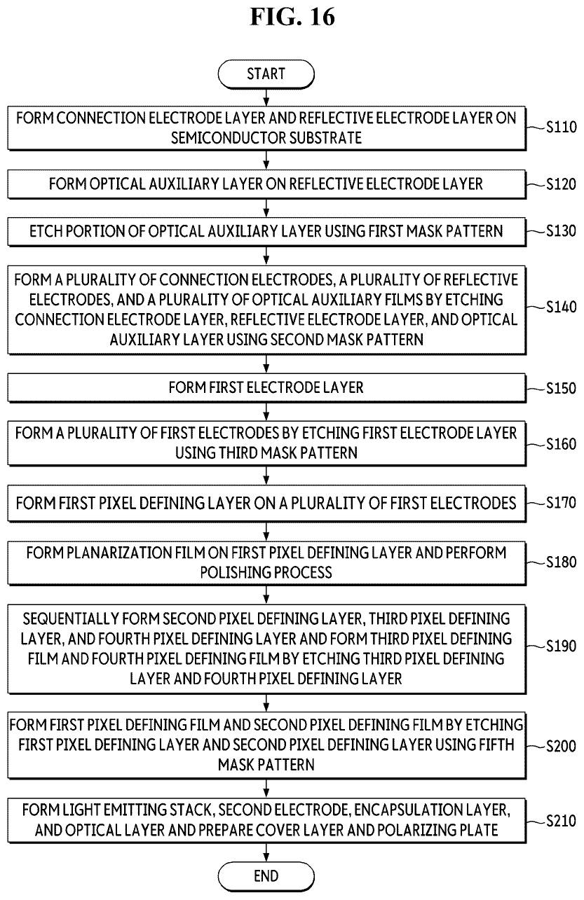

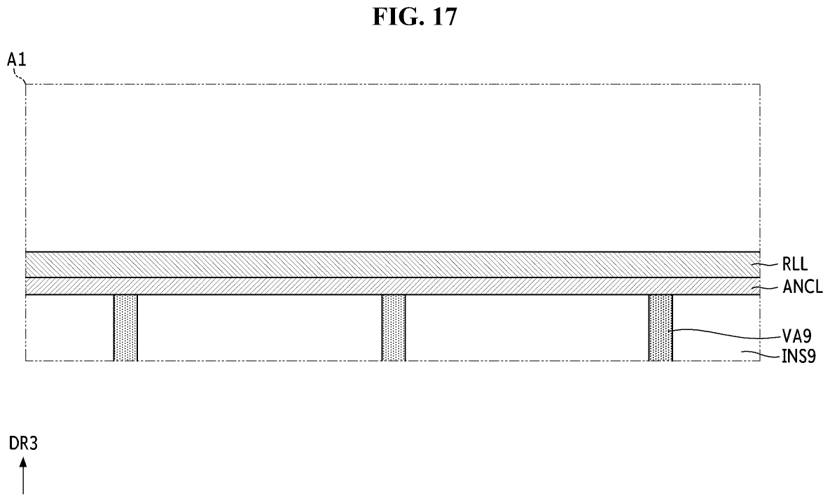

FIG. 16 is a flowchart illustrating a method for manufacturing a display panel according to one or more embodiments. FIGS. 17 to 28 are cross-sectional views illustrating area A1 in detail to describe the method for manufacturing a display panel according to one or more embodiments.

Hereinafter, the method for manufacturing a display panel according to one or more embodiments will be described in detail with reference to FIGS. 7, 16, and 28 to 17.

First, as illustrated in FIGS. 7 and 17, the semiconductor backplane SBP is formed on the semiconductor substrate SSUB, a connection electrode layer ANCL is formed on the semiconductor backplane SBP, and a reflective electrode layer RLL is formed on the connection electrode layer ANCL (S110 of FIG. 16).

The first to eighth conductive layers ML1 to ML8, the first to ninth vias VA1 to VA9, and the first to ninth insulating films INS1 to INS9 of the light-emitting element backplane EBP are formed on the semiconductor substrate SSUB.

For example, the first insulating film INS1 is formed on the semiconductor substrate SSUB, the first vias VA1 penetrating through the first insulating film INS1 to be respectively connected to the contact terminals CTE of the semiconductor substrate SSUB are formed through a photolithography process, and the first conductive layers ML1 respectively connected to the first vias VA1 are formed on the first insulating film INS1 through a photolithography process.

The second insulating film INS2 is formed on the first conductive layers ML1, the second vias VA2 penetrating through the second insulating film INS2 to be respectively connected to the first conductive layers ML1 are formed through a photolithography process, and the second conductive layers ML2 respectively connected to the second vias VA2 are formed on the second insulating film INS2 through a photolithography process.

The third insulating film INS3 is formed on the second conductive layers ML2, the third vias VA3 penetrating through the third insulating film INS3 to be respectively connected to the second conductive layers ML2 are formed through a photolithography process, and the third conductive layers ML3 respectively connected to the third vias VA3 are formed on the third insulating film INS3 through a photolithography process.

The fourth insulating film INS4 is formed on the third conductive layers ML3, the fourth vias VA4 penetrating through the fourth insulating film INS4 to be respectively connected to the third conductive layers ML3 are formed through a photolithography process, and the fourth conductive layers ML4 respectively connected to the fourth vias VA4 are formed on the fourth insulating film INS4 through a photolithography process.

The fifth insulating film INS5 is formed on the fourth conductive layers ML4, the fifth vias VA5 penetrating through the fifth insulating film INS5 to be respectively connected to the fourth conductive layers ML4 are formed through a photolithography process, and the fifth conductive layers ML5 respectively connected to the fifth vias VA5 are formed on the fifth insulating film INS5 through a photolithography process.

The sixth insulating film INS6 is formed on the fifth conductive layers ML5, the sixth vias VA6 penetrating through the sixth insulating film INS6 to be respectively connected to the fifth conductive layers ML5 are formed through a photolithography process, and the sixth conductive layers ML6 respectively connected to the sixth vias VA6 are formed on the sixth insulating film INS6 through a photolithography process.

The seventh insulating film INS7 is formed on the sixth conductive layers ML3, the seventh vias VA7 penetrating through the seventh insulating film INS7 to be respectively connected to the sixth conductive layers ML6 are formed through a photolithography process, and the seventh conductive layers ML7 respectively connected to the seventh vias VA7 are formed on the seventh insulating film INS7 through a photolithography process.

The eighth insulating film INS8 is formed on the seventh conductive layers ML7, the eighth vias VA8 penetrating through the eighth insulating film INS8 to be respectively connected to the seventh conductive layers ML7 are formed through a photolithography process, and the eighth conductive layers ML8 respectively connected to the eighth vias VA8 are formed on the eighth insulating film INS8 through a photolithography process.

The ninth insulating film INS9 is formed on the eighth conductive layers ML8, and the ninth vias VA9 penetrating through the ninth insulating film INS9 to be respectively connected to the eighth conductive layers ML8 are formed in the ninth insulating film INS9 through a photolithography process.

The connection electrode layer ANCL connected to each of the ninth vias VA9 is formed on the ninth insulating film INS9, and the reflective electrode layer RLL is formed on the connection electrode layer ANCL. The connection electrode layer ANCL and the reflective electrode layer RLL may be formed on the entirety of one surface of the semiconductor substrate SSUB.

In addition, the third power conductive layer SVSL3 of the cathode connection portion CCA may be formed by entirely forming a protective layer on the reflective electrode layer RLL and by etching a portion of the protective layer using a mask (e.g., predetermined mask).

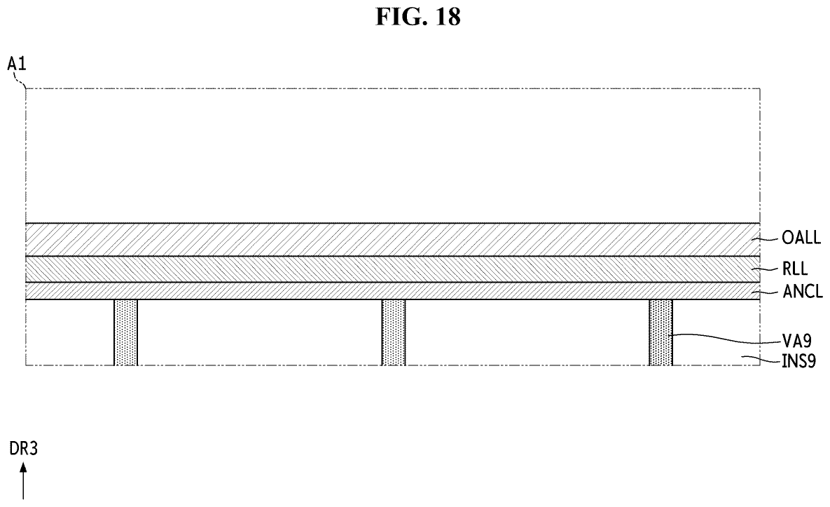

As illustrated in FIGS. 7 and 18, an optical auxiliary layer OALL is formed on the reflective electrode layer RLL (S120 of FIG. 16).

The optical auxiliary layer OALL may be formed on the entirety of one surface of the semiconductor substrate SSUB.

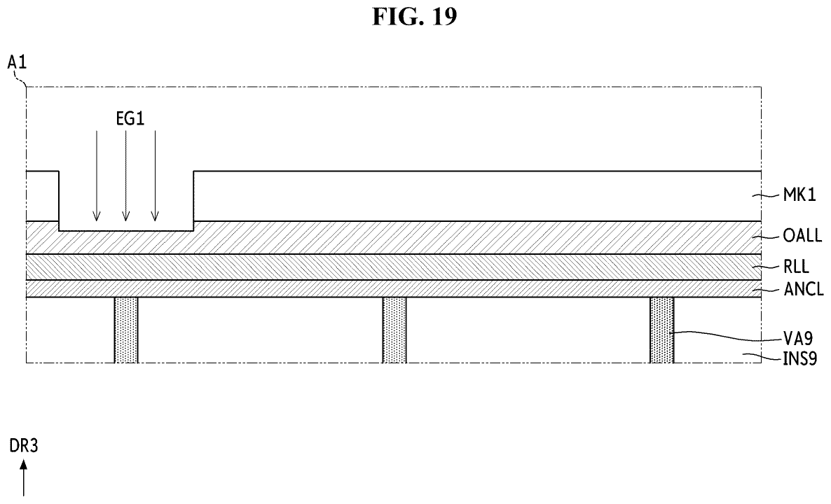

As illustrated in FIGS. 7 and 19, a portion of the optical auxiliary layer OALL is etched using a first mask pattern MK1 (S130 of FIG. 16).

The first mask pattern MK1 may be formed on the optical auxiliary layer OALL, and a portion of the optical auxiliary layer OALL that is not covered by the first mask pattern MK1 may be etched by a first etching material EG1. A thickness of a portion of the optical auxiliary layer OALL may be less than a thickness of the other portion of the optical auxiliary layer OALL. The first mask pattern MK1 may be a photoresist pattern, and the first etching material EG1 may be a dry etching gas.

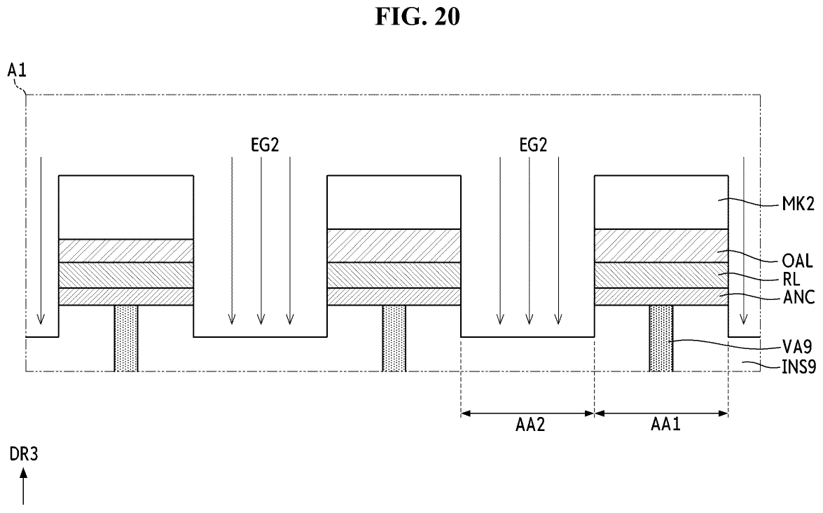

As illustrated in FIGS. 7 and 20, the plurality of connection electrodes ANC, the plurality of reflective electrodes RL, and the plurality of optical auxiliary films OAL are formed by etching the connection electrode layer ANCL, the reflective electrode layer RLL, and the optical auxiliary layer OALL at a time using a second mask pattern MK2 (S140 of FIG. 16).

The second mask pattern MK2 is formed on the optical auxiliary layer OALL, and the plurality of connection electrodes ANC, the plurality of reflective electrodes RL, and the plurality of optical auxiliary films OAL are patterned at a time by a second etching material EG2 using the second mask pattern MK2. The second mask pattern MK2 may be a photoresist pattern, and the second etching material EG2 may be a dry etching gas.

The side surface of the connection electrode ANC, the side surface of the reflective electrode RL, and the side surface of the optical auxiliary film OAL may be aligned with each other. In addition, a manufacturing cost for forming the plurality of connection electrodes ANC, the plurality of reflective electrodes RL, and the plurality of optical auxiliary films OAL may be reduced, and manufacturing efficiency may be increased. Furthermore, the plurality of optical auxiliary films OAL are formed through a photolithography process using a mask without a chemical mechanical polishing (CMP) process, and thus thicknesses of the plurality of optical auxiliary films OAL may be suitably controlled. Therefore, a thickness deviation between the plurality of optical auxiliary films OAL may be reduced, and it is possible to reduce or prevent a difference in light emission efficiency occurring due to a difference in resonance distance caused by the thickness deviation between the plurality of optical auxiliary films OAL for each area of the display panel 100. Accordingly, color blurring occurring on the display panel 100 may be reduced or minimized.

In addition, a portion of the second portion AA2 of the ninth insulating film INS9 that does not overlap the connection electrode ANC in the third direction DR3 may be etched. For this reason, a portion of the first portion AA1 of the ninth insulating film INS9 that overlaps the connection electrode ANC may be exposed.

As illustrated in FIGS. 7, 21, and 22, the plurality of first electrodes AND are formed (S150 and S160 of FIG. 16).

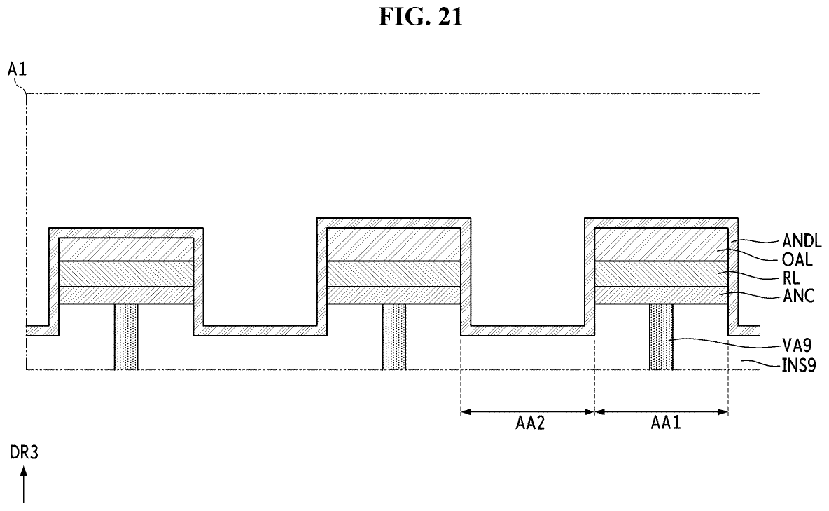

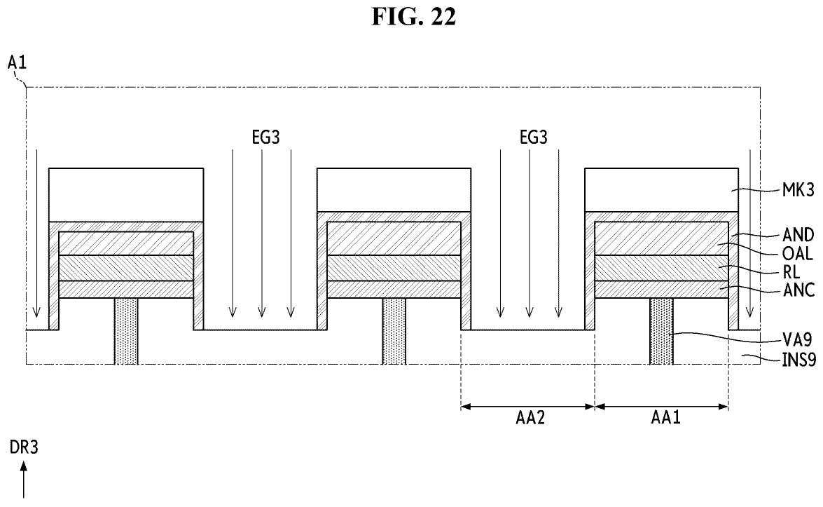

The plurality of first electrodes AND may be formed through a photolithography process. For example, as illustrated in FIG. 21, a first electrode layer ANDL covering the ninth insulating film INS9, the plurality of connection electrodes ANC, the plurality of reflective electrodes RL, and the plurality of optical auxiliary films OAL is entirely formed. As illustrated in FIG. 22, the plurality of first electrodes AND are formed by etching the first electrode layer ANDL by a third etching material EG3 using a third mask pattern MK3. The third mask pattern MK3 may be a photoresist pattern, and the third etching material EG3 may be a dry etching gas.

Each of the plurality of first electrodes AND may be located on each of the side surfaces of the first portion AA1 of the ninth insulating film INS9, the side surfaces of the connection electrode ANC, the side surfaces of the reflective electrode RL, and the upper surface and the side surfaces of the optical auxiliary film OAL. Because each of the plurality of first electrodes AND is in contact with the side surfaces of the reflective electrode RL and the side surfaces of the connection electrode ANC to be electrically connected to the reflective electrode RL and the connection electrode ANC, the number of mask processes may be reduced compared to a case where the first electrode AND of each of the light-emitting elements LE is connected to the reflective electrode RL exposed through the through hole penetrating through the optical auxiliary film OAL, and thus, a manufacturing cost may be reduced and manufacturing efficiency may be increased.

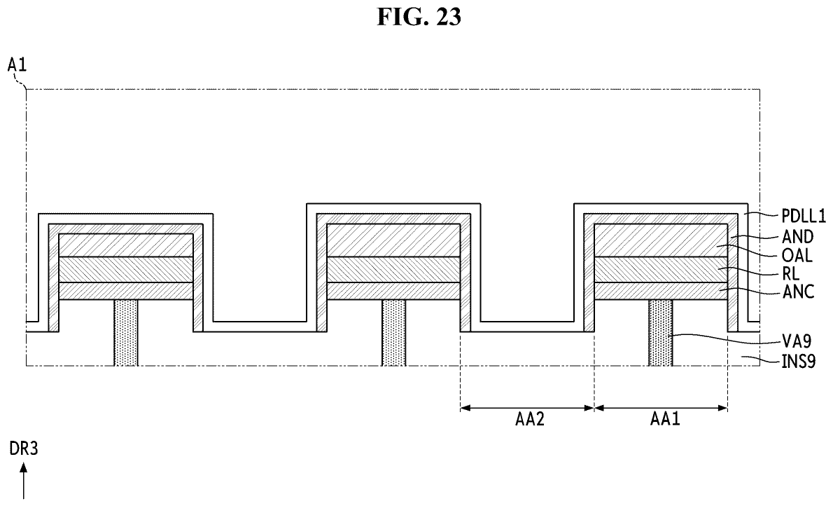

As illustrated in FIGS. 7 and 23, a first pixel-defining layer PDLL1 is formed on the plurality of first electrodes AND (S170 of FIG. 16).

The first pixel-defining layer PDLL1 may be formed on the plurality of first electrodes AND respectively located on the side surfaces of each of the plurality of connection electrodes ANC, the side surfaces of each of the plurality of reflective electrodes RL, and the upper surface and the side surfaces of each of the plurality of optical auxiliary films OAL. The first pixel-defining layer PDLL1 may be formed on the second portion AA2 of the ninth insulating film INS9.

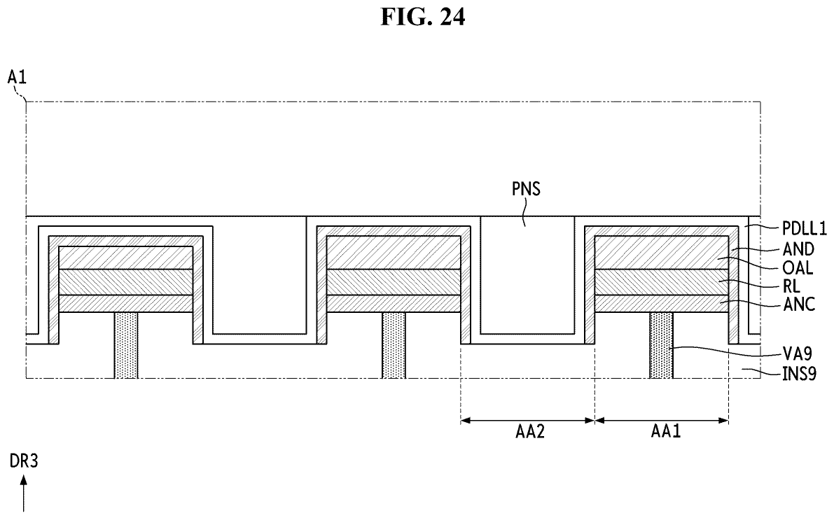

As illustrated in FIGS. 7 and 24, a planarization film PNS is formed on the first pixel-defining layer PDLL1, and a polishing process is performed (S180 of FIG. 16).

The planarization film PNS is a film for planarizing a step due to the first portion AA1 of the ninth insulating film INS9, the connection electrode ANC, the reflective electrode RL, and the optical auxiliary film OAL. The planarization film PNS may be formed on the first pixel-defining film PDL1 located on the first electrode AND located on the side surfaces of the first portion AA1 of the ninth insulating film INS9, the side surfaces of the connection electrode ANC, the side surfaces of the reflective electrode RL, and the side surfaces of the optical auxiliary film OAL. In addition, the planarization film PNS may be formed on the first pixel-defining film PDL1 above the upper surface of the second portion AA2 of the ninth insulating film INS9.

The planarization film PNS may be polished through a chemical mechanical polishing process. In this case, when the planarization film PNS is formed as a silicon oxide (SiOₓ)-based inorganic film and the first pixel-defining layer PDLL1 is formed as a silicon nitride (SiNₓ)-based inorganic film, the first pixel-defining layer PDLL1 may serve as a stopper in the chemical mechanical polishing process.

The planarization film PNS may cover the upper surface of the first pixel-defining film PDL1 located on the upper surface of the first electrode AND located in the first emission area EA1. In the second emission area EA2 and the third emission area EA3, the upper surface of the first pixel-defining layer PDLL1 and the upper surface of the planarization film PNS may be flatly connected to each other (e.g., may be in a same plane).

As illustrated in FIGS. 7, 25, and 26, a second pixel-defining layer PDLL2, a third pixel-defining layer PDLL3, and a fourth pixel-defining layer PDLL4 are sequentially formed, and the third pixel-defining film PDL3 and the fourth pixel-defining film PDL4 are formed by patterning the third pixel-defining layer PDLL3 and the fourth pixel-defining layer PDLL4 (S190 of FIG. 16).

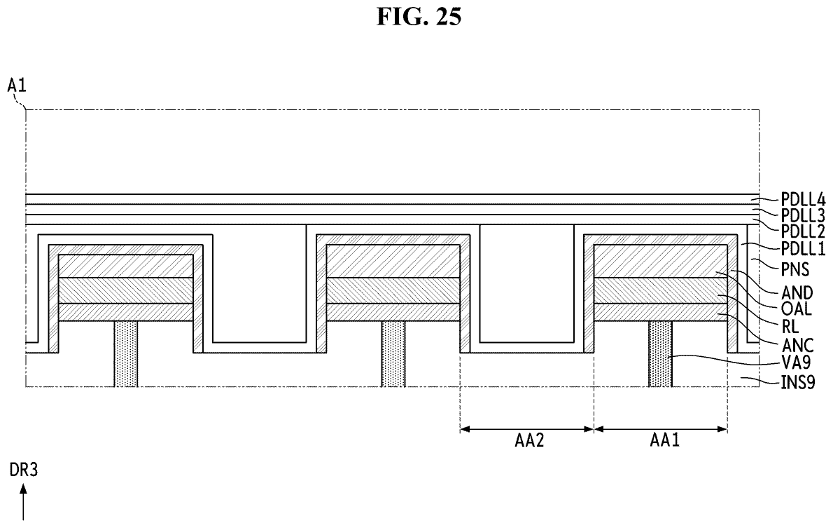

As illustrated in FIG. 25, the second pixel-defining layer PDLL2 may be formed on the first pixel-defining layer PDLL1 and the planarization film PNS, the third pixel-defining layer PDLL3 may be formed on the second pixel-defining layer PDLL2, and the fourth pixel-defining layer PDLL4 may be formed on the third pixel-defining layer PDLL3.

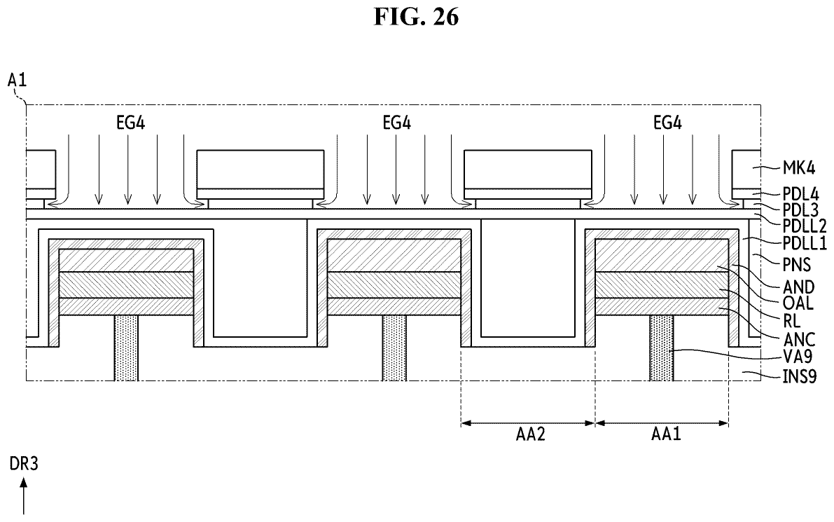

As illustrated in FIG. 26, a fourth mask pattern ML4 is formed on the fourth pixel-defining layer PDLL4, and the third pixel-defining layer PDLL3 and the fourth pixel-defining layer PDLL4 that are not covered by the fourth mask pattern MK4 are patterned at a time by a fourth etching material EG4. The fourth mask pattern MK4 may be a photoresist pattern, and the fourth etching material EG4 may be a dry etching gas.

As illustrated in FIG. 26, a rate at which the third pixel-defining layer PDLL3 is etched by the fourth etching material EG4 may be higher than a rate at which the fourth pixel-defining layer PDLL4 is etched by the fourth etching material EG4. Therefore, the third pixel-defining film PDL3 and the fourth pixel-defining film PDL4 having the cross-sectional structure with the eaves shape or the mushroom shape may be formed.

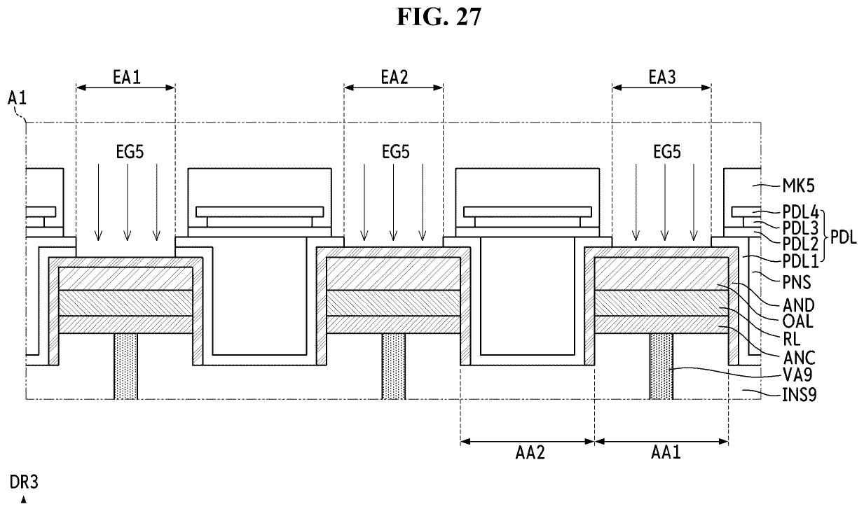

As illustrated in FIGS. 7 and 27, the first pixel-defining film PDL1 and the second pixel-defining film PDL2 are formed by forming a fifth mask pattern MK5 covering the third pixel-defining film PDL3 and the fourth pixel-defining film PDL4, and then etching the first pixel-defining layer PDLL1 and the second pixel-defining layer PDLL2 by a fifth etching material EG5 (S200 of FIG. 16).

In the first emission area EA1, the planarization film PNS covering the upper surface of the first pixel-defining film PDL1 located on the upper surface of the first electrode AND at the first emission area EA1 may be etched together with the first pixel-defining layer PDLL1 and the second pixel-defining layer PDLL2. The fifth mask pattern MK5 may be a photoresist pattern, and the fifth etching material EG5 may be a dry etching gas.

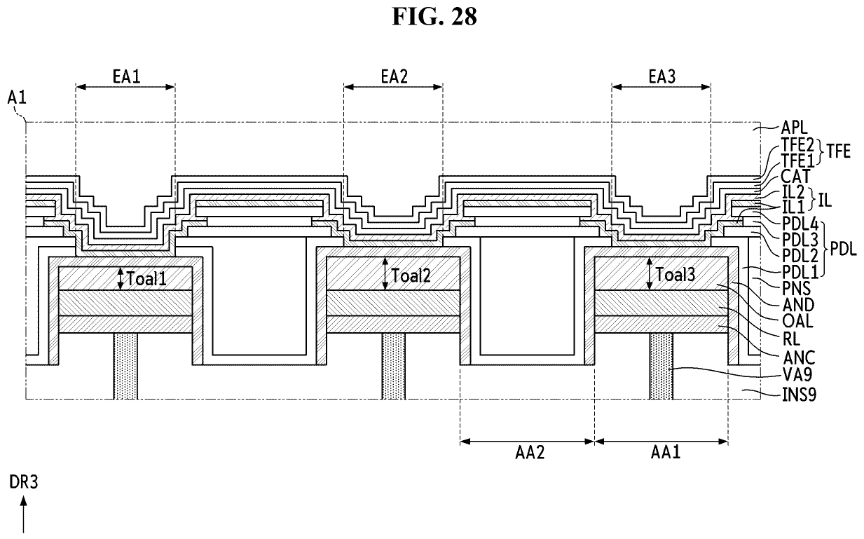

As illustrated in FIGS. 7 and 28, the light-emitting stack IL, the second electrode CAT, the encapsulation layer TFE, and the optical layer OPL are formed, and the cover layer CVL and the polarizing plate POL are attached (S210 of FIG. 16).

The first stack layer IL1 of the light-emitting stack IL may be formed on the plurality of first electrodes AND and the pixel-defining film PDL. The first stack layer IL1 of the light-emitting stack IL may be disconnected by the cross-sectional structure with the eaves shape or the mushroom shape by the third pixel-defining film PDL3 and the fourth pixel-defining film PDL4. In this case, the charge generation layer CGL located between the first stack layer IL1 and the second stack layer IL2 may also be disconnected. Therefore, it is possible to reduce or prevent a current from flowing between the emission areas EA1, EA2, and EA3 neighboring to each other due to the charge generation layer CGL of the light-emitting stack IL. Accordingly, it is possible to reduce or prevent the likelihood of the light-emitting stack IL in the emission areas EA1, EA2, and EA3 neighboring each other being affected by the current and emitting light other than originally intended light.

The second electrode CAT is formed on the light-emitting stack IL. The second electrode CAT may be connected to the fourth power conductive layer SVSL4 of the first driving voltage line VSL exposed without being covered by the pixel-defining film PDL in the cathode connection portion CCA located in the non-display area NDA.

The first encapsulation inorganic film TFE1 and the second encapsulation inorganic film TFE2 of the encapsulation layer TFE are sequentially formed on the second electrode CAT. The first encapsulation inorganic film TFE1 may be formed through a CVD process, and the second encapsulation inorganic film TFE2 may be formed through an ALD process.

The organic film APL is formed on the encapsulation layer TFE, and the first color filters CF1 overlapping the first emission areas EA1, the second color filters CF2 overlapping the second emission areas EA2, and the third color filters CF3 overlapping the third emission areas EA3 are formed on the organic film APL.

The plurality of lenses LNS are formed on the first color filters CF1, the second color filters CF2, and the third color filters CF3, respectively. That is, the plurality of lenses LNS may be formed to correspond to the color filters CF1, CF2, and CF3 in a one-to-one manner.

The filling layer FIL is formed on the plurality of lenses LNS, and the cover layer CVL is provided on the filling layer FIL.

The cover layer CVL may be a glass substrate or a polymer resin, such as a resin. When the cover layer CVL is the glass substrate, the cover layer CVL may serve as an encapsulation substrate, and the filling layer FIL may serve to adhere the cover layer CVL. When the cover layer CVL is the polymer resin, such as the resin, the cover layer CVL may be directly applied onto the filling layer FIL.

The polarizing plate POL is attached onto the cover layer CVL.

Alternatively, as illustrated in FIGS. 14 and 15, the first light-emitting layer IL1_1 may be formed on the first electrode AND of each of the first emission areas EA1, the second light-emitting layer IL2_1 may be formed on the first electrode AND of each of the second emission areas EA2, and the third light-emitting layer IL3_1 may be formed on the first electrode AND of each of the third emission areas EA3. In this case, the second electrode CAT may be formed on the first light-emitting layer IL1_1, the second light-emitting layer IL2_1, and the third light-emitting layer IL3_1. In addition, the first color filters CF1, the second color filters CF2, the third color filters CF3, the plurality of lenses LNS, and the filling layer FIL may be omitted.

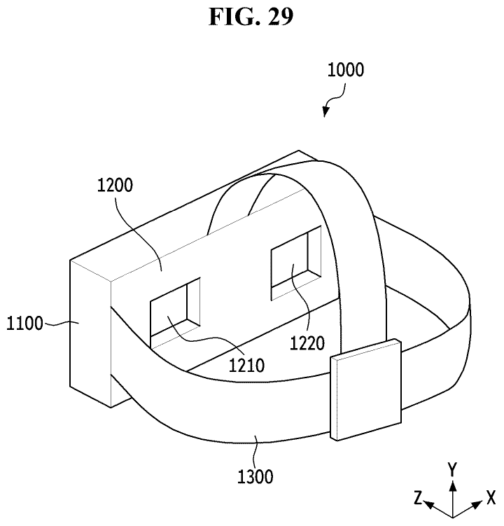

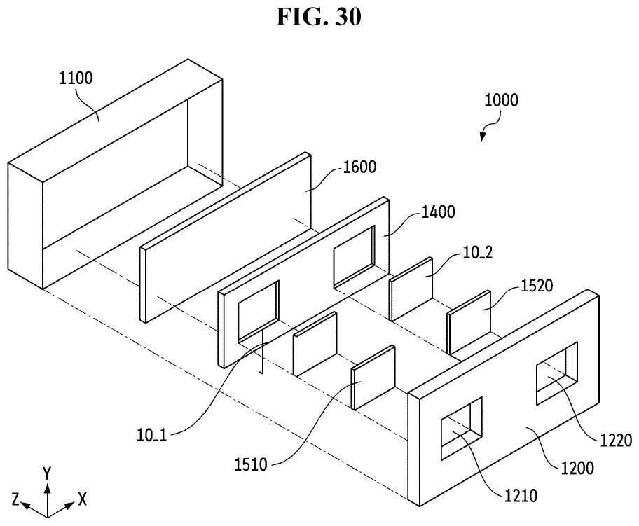

FIG. 29 is a perspective view illustrating a head-mounted display device according to one or more embodiments. FIG. 30 is an exploded perspective view illustrating an example of the head-mounted display device of FIG. 29.

Referring to FIGS. 29 and 30, a head-mounted display device 1000 according to one or more embodiments includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 and 2, and a description of the first display device 10_1 and the second display device 10_2 is thus omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and located between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through a connector. The control circuit board 1600 may convert an image source input from the outside into digital video data DATA, and may transmit the digital video data DATA to the first display device 10_1 and the second display device 10_2 through the connector.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing 1100 serves to house the first display device 10_1, the second display device 10_2, the middle frame 1400, the first optical member 1510, the second optical member 1520, and the control circuit board 1600. The housing cover 1200 is located to cover opened one surface of the display device housing 1100. The housing cover 1200 may include the first eyepiece 1210 on which the user's left eye is located and the second eyepiece 1220 on which the user's right eye is located. It has been illustrated in FIGS. 29 and 30 that the first eyepiece 1210 and the second eyepiece 1220 are separately located, but one or more embodiments of the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

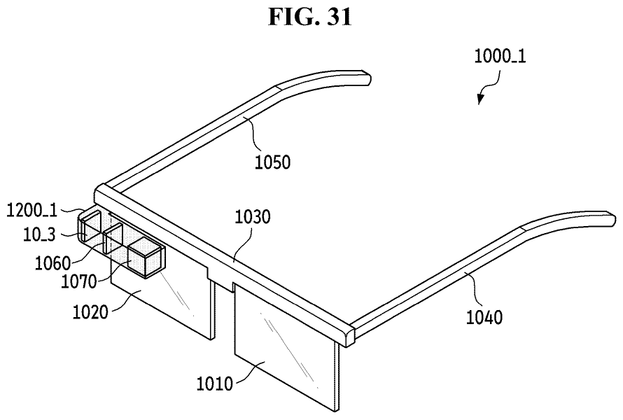

The head-mounted band 1300 serves to fix the display device housing 1100 to a user's head so that the first eyepiece 1210 and the second eyepiece 1220 of the housing cover 1200 may be maintained in a state where they are located on the user's left eye and right eye, respectively. When the display device housing 1200 is implemented to have a light weight and a small size, the head-mounted display device 1000 may include an eyeglass frame as illustrated in FIG. 31 instead of the head-mounted band 800.

In addition, the head-mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (Wi-Fi®) module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 31 is a perspective view illustrating a head-mounted display according to one or more other embodiments.

Referring to FIG. 31, a head-mounted display device 1000_1 according to one or more other embodiments may be a glasses-type display device in which a display device housing 1200_1 is implemented to have a light weight and a small size. The head-mounted display device 1000_1 according to one or more other embodiments may include a display device 10_3, a left eye lens 1010, a right eye lens 1020, a support frame 1030, glasses frame legs 1040 and 1050, an optical member 1060, an optical path conversion member 1070, and a display device housing 1200_1.

The display device housing 1200_1 may include the display device 10_3, the optical member 1060, and the optical path conversion member 1070. An image displayed on the display device 10_3 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 31 that the display device housing 1200_1 is located at a right end of the support frame 1030, but one or more embodiments of the present disclosure is not limited thereto. For example, the display device housing 1200_1 may be located at a left end of the support frame 1030, and in this case, an image of the display device 10_3 may be provided to a user's left eye. Alternatively, the display device housing portions 1200_1 may be located at both the left and right ends of the support frame 1030, and in this case, the user may view an image displayed on the display device 10_3 through both his/her left and right eyes.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, with functional equivalents thereof to be included therein.

What is claimed is:

1. A display device comprising:
a first sub-pixel comprising a first emission area for emitting first light;
a second sub-pixel comprising a second emission area for emitting second light;
a third sub-pixel comprising a third emission area for emitting third light;
a substrate;
an insulating film above the substrate;
connection electrodes above the insulating film;
reflective electrodes respectively above the connection electrodes;
optical auxiliary films respectively above the reflective electrodes; and
first electrodes respectively above the optical auxiliary films,
wherein a thickness of a first of the optical auxiliary films at the first emission area is less than a thickness of a second of the optical auxiliary films at the second emission area.

2. The display device of claim 1, wherein the thickness of the first of the optical auxiliary films is less than a thickness of a third of the optical auxiliary films at the third emission area.

3. The display device of claim 1, wherein the thickness of the second of the optical auxiliary films is the same as a thickness of a third of the optical auxiliary films at the third emission area.

4. The display device of claim 1, wherein the thickness of the second of the optical auxiliary films is less than a thickness of a third of the optical auxiliary films at the third emission area.

5. The display device of claim 1, wherein a height of a first of the first electrodes at the first emission area is less than a height of a second of the first electrodes at the second emission area.

6. The display device of claim 5, wherein the height of the first of the first electrodes is less than a height of a third of the first electrodes at the third emission area.

7. The display device of claim 5, wherein the height of the second of the first electrodes is the same as a height of a third of the first electrodes at the third emission area.

8. The display device of claim 5, wherein the height of the second of the first electrodes is less than a height of a third of the first electrodes at the third emission area.

9. The display device of claim 1, wherein the first electrodes are respectively on side surfaces of the connection electrodes, side surfaces of the reflective electrodes, and an upper surface and side surfaces of the optical auxiliary films.

10. The display device of claim 9, further comprising:
a first pixel-defining film covering a portion of upper surfaces of the first electrodes above the optical auxiliary films, and covering the first electrodes on the side surfaces of the connection electrodes, the side surfaces of the reflective electrodes, and the side surfaces of the optical auxiliary films; and
a planarization film above the first pixel-defining film.

11. The display device of claim 10, wherein the planarization film is above an upper surface of a first of the first electrodes at the first emission area.

12. The display device of claim 11, wherein an upper surface of the first pixel-defining film at the second emission area and at the third emission area and an upper surface of the planarization film are flatly connected to each other.

13. The display device of claim 10, wherein the planarization film is above the upper surfaces of a first one of the first electrodes at the first emission area and a second one of the first electrodes at the second emission area.

14. The display device of claim 13, wherein a thickness of the planarization film above the upper surface of the first of the first electrodes is less than a thickness of the planarization film above an upper surface of the second of the first electrodes.

15. The display device of claim 13, wherein an upper surface of the first pixel-defining film above an upper surface of a third of the first electrodes at the third emission area and an upper surface of the planarization film are flatly connected to each other, and
wherein a thickness of the planarization film above the upper surface of the first of the first electrodes and the upper surface of the second of the first electrodes is less than a thickness of the planarization film above the upper surface of the third of the first electrodes.

16. The display device of claim 10, further comprising:
a second pixel-defining film above the first pixel-defining film and the planarization film; and
a third pixel-defining film above the second pixel-defining film,
wherein a length of the second pixel-defining film in one direction is less than a length of the third pixel-defining film in the one direction.

17. The display device of claim 10, further comprising:
a first power conductive layer above the insulating film, and comprising a same material as the connection electrode;
a second power conductive layer above the first power conductive layer, and comprising a same material as the reflective electrode;
a third power conductive layer above the second power conductive layer; and
a fourth power conductive layer connected to the third power conductive layer through a contact hole penetrating through the optical auxiliary film above the third power conductive layer;
a light-emitting layer above the first electrodes; and
a second electrode above the light-emitting layer, and connected to the portion of the upper surface of the fourth power conductive layer,
wherein the first pixel-defining film exposes a portion of an upper surface of the fourth power conductive layer.

18. A head-mounted display comprising:
at least one display device comprising a first sub-pixel comprising a first emission area for emitting first light, a second sub-pixel comprising a second emission area for emitting second light, and a third sub-pixel comprising a third emission area for emitting third light;
a display device housing in which the at least one display device is housed; and
an optical member magnifying a display image of the at least one display device or converting an optical path,
wherein the at least one display device comprises:
a substrate;
an insulating film above the substrate;
connection electrodes above the insulating film;
reflective electrodes respectively above the connection electrodes;
optical auxiliary films respectively above the reflective electrodes; and
first electrodes respectively above the optical auxiliary films, and
a thickness of a first of the optical auxiliary films at the first emission area is less than a thickness of a second of the optical auxiliary films at the second emission area among the optical auxiliary films.

19. An electronic device comprising a display device comprising:
a first sub-pixel comprising a first emission area for emitting first light;
a second sub-pixel comprising a second emission area for emitting second light;
a third sub-pixel comprising a third emission area for emitting third light;
a substrate;
an insulating film above the substrate;
connection electrodes above the insulating film;
reflective electrodes respectively above the connection electrodes;
optical auxiliary films respectively above the reflective electrodes; and
first electrodes respectively above the optical auxiliary films,
wherein a thickness of a first of the optical auxiliary films at the first emission area is less than a thickness of a second of the optical auxiliary films at the second emission area.

20. The electronic device of claim 19, wherein the electronic device comprises a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
